(19) United States
(12) Patent Application Publication
(10) Pub. No.: US 2026/0244059 A1
(43) Pub. Date: Aug. 20, 2026

(54) Display Substrate and Display Device

(71) Applicants: BEIJING BOE TECHNOLOGY DEVELOPMENT CO., LTD., Beijing (CN); BOE TECHNOLOGY GROUP CO., LTD., Chaoyang District, Beijing (CN)

(72) Inventors: Hehe Hu, Beijing (CN); Weili Zhao, Beijing (CN); Peirou Li, Beijing (CN); Nianqi Yao, Beijing (CN); Kun Zhao, Beijing (CN); Ce Ning, Beijing (CN); Zheng Fang, Beijing (CN); Zhenyu Zhang, Beijing (CN); Minghua Xuan, Beijing (CN); Zhengliang Li, Beijing (CN); Hui Guo, Beijing (CN); Guangcai Yuan, Beijing (CN); Xue Dong, Beijing (CN)

(21) Appl. No.: 18/992,762

(22) PCT Filed: May 30, 2024
(86) PCT No.: PCT/CN2024/096457

§ 371 Date: Jan. 9, 2025

(30) Foreign Application Priority Data
May 30, 2023 (WO) PCT/CN2023/097164
Nov. 30, 2023 (CN) 202311630471.6

(51) Int. Cl. G02F 1/1362; G02F 1/1368

(52) U.S. Cl. CPC G02F 1/13629; G02F 1/136209; G02F 1/136222; G02F 1/136227; G02F 1/1368

(57) ABSTRACT

A display substrate is provided. The display substrate includes a first substrate, a first insulating layer a first via hole, a semiconductor layer and a connecting electrode. The first via hole at least penetrates the first insulating layer and expos s a portion of a first signal line. The semiconductor laver includes a first portion, a second portion and a channel structure located between the first portion and the second portion. An orthogonal projection of the first portion on the first substrate partially overlaps with an orthogonal projection of the first signal line on the first substrate, and an orthogonal projection of the channel structure on the first substrate is located within an orthogonal projection of a first pattern on the first substrate. At least a portion of the connecting electrode is located in the first via hole and connected to the first portion and the first signal line.

### CROSS-REFERENCE TO RELATED APPLICATIONS

This application is the national phase of International Patent Application No. PCT/CN2024/096457, filed on May 30, 2024, and claims priority to International Patent Application No. PCT/CN2023/097164, filed on May 30, 2023, and Chinese Patent Application No. 202311630471.6, filed on Nov. 30, 2023, the disclosures of which are hereby incorporated by reference in their entireties.

### BACKGROUND OF THE INVENTION

### FIELD OF THE INVENTION

The present disclosure relates to the field of display technologies, and in particular, to a display substrate and a display device.

### DESCRIPTION OF RELATED ART

With the continuous development of display technologies, display devices have been widely used, and people have higher and higher requirements for display devices. High pixels per inch (PPI for short) is an important development direction of the display devices. Common display devices may include liquid crystal display devices (LCD) and organic light-emitting diode display devices (OLED). Due to the simpler pixel circuit structure of the liquid crystal display devices (which may include fewer thin film transistors and capacitors), the liquid crystal display devices have more advantages in ultra-high pixel density (e.g., greater than or equal to 1000 PPI). As the pixel density is increased, aperture ratio of the display devices is gradually decreased, thereby resulting in a decrease in the transmittance (transmittance/light transmittance) of the display devices. How to improve the aperture ratio and light transmittance of the display devices is an important technical issue facing liquid crystal display devices.

### SUMMARY OF THE INVENTION

In an aspect, a display substrate is provided. The display substrate includes an array substrate and a color filter substrate. The array substrate includes a first substrate, a first conductive layer, a first insulating layer, a first via hole, a semiconductor layer and a connecting electrode. The first conductive layer is disposed on a side of the first substrate, and includes at least one first signal line and a first pattern that are spaced apart. The first insulating layer is disposed on a side of the first conductive layer away from the first substrate. The first via hole at least penetrates the first insulating layer and exposes at least a portion of the first signal line. The semiconductor layer is disposed on a side of the first insulating layer away from the first substrate, and includes a semiconductor pattern. The semiconductor pattern includes a first portion, a second portion and a channel structure located between the first portion and the second portion. An orthogonal projection of the first portion on the first substrate partially overlaps with an orthogonal projection of the first signal line on the first substrate, and an orthogonal projection of the channel structure on the first substrate is located within a range of an orthogonal projection of the first pattern on the first substrate. The connecting electrode is disposed on a side of the semiconductor layer away from the first substrate. At least a portion of the connecting electrode is located in the first via hole and connected to the first portion and the first signal line.

In some embodiments, the array substrate further includes a first electrode; the first electrode is disposed on a side of a film layer where the connecting electrode is located away from the first substrate, and an orthogonal projection of the first electrode on the first substrate covers the orthogonal projection of the first signal line on the first substrate.

In some embodiments, the first electrode includes a first extending segment; an extending direction of the first extending segment is the same as an extending direction of the first signal line; an orthogonal projection of the first extending segment on the first substrate covers the orthogonal projection of the first signal line on the first substrate, and there is a first interval between boundaries, proximate to each other, of the orthogonal projections of the first extending segment and the first signal line on the first substrate; the first interval is in a range from 2 μm to 5 μm.

In some embodiments, the semiconductor layer further includes a second electrode connected to the second portion and integrally disposed with the second portion.

In some embodiments, there is a second interval between an orthogonal projection of the second electrode on the first substrate and an orthogonal projection of the first pattern on the first substrate, and there is a third interval between the orthogonal projection of the second electrode on the first substrate and the orthogonal projection of the first signal line on the first substrate.

In some embodiments, the first insulating layer includes a first groove portion that is concave in a direction proximate to the first substrate, and at least a portion of the first groove portion is located between the first signal line and the first pattern. The second interval is greater than or equal to 2 μm, and/or the third interval is greater than or equal to 5 μm.

In some embodiments, the array substrate further includes a planarization layer; the planarization layer is located between the first conductive layer and the first insulating layer; a surface of the planarization layer away from the first substrate is a flat surface. Orthogonal projections of the first conductive layer, the second interval and the third interval on the first substrate are located within a range of an orthogonal projection of the planarization layer on the first substrate; the second interval is greater than or equal to 1 μm, and/or the third interval is greater than or equal to 3 μm.

In some embodiments, the first insulating layer includes a first groove portion that is concave in a direction proximate to the first substrate, and at least a portion of the first groove portion is located between the first signal line and the first pattern; the first groove portion includes two first side walls disposed opposite to each other. The first portion includes two first sub-portions covering the two first side walls, and a second sub-portion covering other regions of the first insulating layer; a thickness of the first sub-portion is less than a thickness of the second sub-portion.

In some embodiments, the array substrate further includes a second insulating layer; the second insulating layer is disposed between the semiconductor layer and a film layer where the connecting electrode is located. One of the two first sub-portions proximate to the first signal line is a target sub-portion; the first via hole penetrates the second insulating layer and exposes the target sub-portion; the connecting electrode covers the target sub-portion; a dimension of the channel structure in a direction perpendicular to the first substrate is greater than or equal to 300 Å.

In some embodiments, the array substrate further includes a second insulating layer; the second insulating layer is disposed between the semiconductor layer and a film layer where the connecting electrode is located. One of the two first sub-segments proximate to the first signal line is a target sub-segment. The first via hole further penetrates the second insulating layer, and there is an interval between the first via hole and the target sub-segment; a dimension of the channel structure in a direction perpendicular to the first substrate is greater than or equal to 100 Å.

In some embodiments, the array substrate further includes a second insulating layer; the second insulating layer is disposed between the semiconductor layer and a film layer where the connecting electrode is located. One of the two first sub-segments proximate to the first signal line is a target sub-segment; the first via hole penetrates the second insulating layer and exposes the target sub-segment; there is an interval between the connecting electrode and the target sub-segment; a dimension of the channel structure in a direction perpendicular to the first substrate is greater than or equal to 600 Å.

In some embodiments, along a direction perpendicular to the first substrate, a dimension of the first conductive layer is in a range from 0.4 μm to 0.8 μm; and/or, in a cross section perpendicular to the first substrate and perpendicular to an extending direction of an edge of the first conductive layer, the side wall of the first conductive layer and the first substrate have a first included angle therebetween, and the first included angle is less than or equal to 50°.

In some embodiments, the array substrate further includes a planarization layer; the planarization layer is located between the first conductive layer and the first insulating layer, and a surface of the planarization layer away from the first substrate is a flat surface; the planarization layer at least covers the first signal line, the first pattern, and an interval between the first signal line and the first pattern. The semiconductor layer further includes a second electrode; the second electrode is connected to the second portion and integrally disposed with the second portion; at least a portion of an orthogonal projection of the second electrode on the first substrate does not overlap with at least a portion of an orthogonal projection of the planarization layer on the first substrate.

In some embodiments, in a cross section perpendicular to the first substrate and perpendicular to an extending direction of a side wall of the planarization layer, the side wall of the planarization layer and the first substrate have a second included angle therebetween, and the second included angle is less than or equal to 50°; and/or an interval between the surface of the planarization layer away from the first substrate and the first substrate is in a range from 0.4 μm to 0.8 μm.

In some embodiments, the at least one first signal line includes a plurality of first signal lines; the plurality of first signal lines are disposed at intervals along a first direction and extend along a second direction. The array substrate further includes a plurality of signal line groups; the plurality of signal line groups are arranged at intervals along the second direction and extend along the first direction. The plurality of first signal lines and the plurality of signal line groups intersect each other to form a grid structure; a region where an orthogonal projection of any one of the plurality of signal line groups on the first substrate overlaps with an orthogonal projection of any one of the plurality of first signal lines on the first substrate protrudes toward a side away from the first substrate to form a columnar structure. The color filter substrate includes at least one spacer; the spacer is in a strip shape and extends along the first direction; an orthogonal projection of the spacer on the array substrate partially overlaps with the first signal line and the signal line group. The signal line group includes a wiring region; a position where at least one of the signal line groups intersects with the first signal line is provided with the wiring region; in the wiring region, the orthogonal projection of the spacer on the array substrate does not overlap with the columnar structure.

In some embodiments, a side of the spacer away from the color filter substrate abuts against a portion of the columnar structure.

In some embodiments, the side of the spacer away from the color filter substrate is at a same distance from the color filter substrate.

In some embodiments, in the wiring region, the signal line group protrudes toward the first direction.

In some embodiments, a dimension of the spacer along the first direction is greater than a distance between two adjacent first signal lines.

In some embodiments, the signal line group and the connecting electrode are made of a same material are disposed on a same layer.

In some embodiments, the signal line group includes one or more second signal line; an orthogonal projection of the one or more second signal line on the color filter substrate overlaps with the spacer; a dimension of any one of the one or more second signal line in the second direction is C1; a dimension of an end of the spacer proximate to the array substrate in the second direction is C4; C4 is greater than C1.

In some embodiments, the signal line group includes one or more second signal line and one or more third signal line; the orthogonal projection of the spacer on the array substrate covers a region between the second signal line and the third signal line; the orthogonal projection of the spacer on the array substrate partially overlaps with the second signal line; the orthogonal projection of the spacer on the array substrate partially overlaps with the third signal line.

In some embodiments, a dimension of the second signal line in the second direction is C1, and a dimension of the third signal line in the second direction is C2; an interval between the second signal line and the third signal line is C3, and a dimension of an end of the spacer proximate to the array substrate in the second direction is C4; C1, C2, C3 and C4 satisfy: C2>C1, C4=C3+C1; or, C1, C2, C3 and C4 satisfy: C1>C2, C4=C3+C2.

In some embodiments, a position where at least one of the one or more second signal lines and/or at least one of the one or more third signal lines intersects the first signal line is provided with the wiring region.

In some embodiments, the array substrate includes a first electrode, and the third signal line is connected to the first electrode at a side of the protrusion in the wiring region along the first direction.

In some embodiments, an orthogonal projection of one of the at least one spacer on the array substrate has overlapping regions with at least thirteen of the at least one first signal line, and has an overlapping region with one of the plurality of signal line groups; at least eleven of intersection positions between the at least thirteen first signal lines and the signal line group are provided with the wiring region.

In some embodiments, the grid structure formed by the plurality of the first signal lines and the plurality of the signal line groups defines a plurality of pixel regions; on average, every twenty-four pixel regions in the display substrate is provided with one of the at least one spacer.

In some embodiments, the orthogonal projection of the spacer on the array substrate partially overlaps with the signal line group or the first signal line; the spacer includes a main spacer region with a first thickness and a secondary spacer region with a second thickness, and the first thickness is greater than the second thickness; an orthogonal projection of the main spacer region on the array substrate has an overlapping region with the first signal line, and an orthogonal projection of the main spacer region on the array substrate does not overlap with the signal line group.

In some embodiments, the orthogonal projection of the main spacer region on the array substrate has overlapping regions with at least two of the at least one first signal line.

In some embodiments, the color filter substrate further includes a black matrix; an orthogonal projection of the black matrix on the array substrate covers the spacer, the first signal line and the signal line group.

In some embodiments, the black matrix includes a first portion, and an orthogonal projection of the first portion on the array substrate covers the semiconductor pattern, the first pattern, and the region where the signal line group overlaps with the first signal line; there is a fourth interval D4 between boundaries, of orthogonal projections of the first portion and a surface of the spacer proximate to the array substrate on the array substrate, that are proximate to each other; the fourth interval is in a range from 20 μm to 40 μm.

In some embodiments, the black matrix further includes a second portion; an orthogonal projection of the second portion on the array substrate covers a region of the signal line group that is staggered with the first pattern and the semiconductor pattern in the second direction, and a portion of the black matrix covering a same signal line group includes first portions and the second portions that are staggered along the first direction; there is a fifth interval between boundaries, of orthogonal projections of the second portion and the signal line group on the array substrate, that are proximate to each other; the fifth interval is in a range from 3 μm to 6 μm.

In some embodiments, the first insulating layer includes a first groove portion that is concave in a direction proximate to the first substrate, and at least a portion of the first groove portion is located between the first signal line and the first pattern. The black matrix further includes a third portion; an orthogonal projection of the third portion on the array substrate covers the first signal line, and there is a sixth interval between boundaries, of orthogonal projections of the third portion and the first signal line on the first substrate, that are proximate to each other; the sixth interval is in a range from 0.5 μm to 2 μm.

In some embodiments, a transmittance of the display substrate is greater than or equal to 6%.

In some embodiments, the array substrate further includes a planarization layer; the planarization layer is located between the first conductive layer and the first insulating layer, and a surface of the planarization layer away from the first substrate is a flat surface; the planarization layer includes a first flat portion, and the first flat portion covers the first signal line. The black matrix includes a third portion; an orthogonal projection of the third portion on the array substrate covers the first flat portion, and there is a seventh interval between boundaries, of orthogonal projections of the third portion and the first flat portion on the first substrate, that are proximate to each other; the seventh interval is in a range from 0.5 μm to 2 μm.

In some embodiments, a transmittance of the display substrate is greater than or equal to 9%.

In another aspect, a display device is provided. The display device includes the display substrate according to any of the above embodiments.

### BRIEF DESCRIPTION OF THE DRAWINGS

In order to describe technical solutions in the present disclosure more clearly, the accompanying drawings to be used in some embodiments of the present disclosure will be introduced briefly. Obviously, the accompanying drawings to be described below are merely drawings of some embodiments of the present disclosure, and a person of ordinary skill in the art can obtain other drawings according to these accompanying drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a structural diagram of a display device, in accordance with some embodiments;

FIG. 2 is a diagram showing a composition structure of a display substrate, in accordance with some embodiments;

FIG. 3 is a plan view showing a structure of an array substrate, in accordance with some embodiments;

FIG. 4 is an enlarged partial view of the A1 region in FIG. 3;

FIG. 5 is a sectional view taken along the section line B1-B1 in FIG. 4;

FIG. 6 is a plan view showing a structure of a pixel region, in accordance with some embodiments;

FIG. 7 is another plan view showing a structure of an array substrate, in accordance with some embodiments;

FIG. 8 is an enlarged partial view of the A2 region in FIG. 7;

FIG. 9 is a sectional view taken along the section line B2-B2 in FIG. 8;

FIG. 10 is a sectional view taken along the section line B3-B3 in FIG. 3;

FIGS. 11 and 12 are diagrams showing a manufacturing process of an array substrate, in accordance with some embodiments;

FIG. 13 is an enlarged partial view of a thin film transistor, in accordance with some embodiments;

FIG. 14 is another enlarged partial view of a thin film transistor, in accordance with some embodiments;

FIG. 15 is a sectional view taken along the section line B4-B4 in FIG. 14;

FIG. 16 is yet another enlarged partial view of a thin film transistor, in accordance with some embodiments;

FIG. 17 is a sectional view taken along the section line B5-B5 in FIG. 16;

FIG. 18 is a diagram showing a sectional structure of an array substrate, in accordance with some embodiments;

FIG. 19 is a diagram showing another sectional structure of an array substrate, in accordance with some embodiments;

FIG. 20A is yet another enlarged partial view of a thin film transistor, in accordance with some embodiments;

FIG. 20B is yet another enlarged partial view of a thin film transistor, in accordance with some embodiments;

FIG. 21 is a sectional view taken along the section line B6-B6 in FIG. 3;

FIG. 22 is a sectional view taken along the section line B7-B7 in FIG. 7;

FIG. 23 is a top view of a partial structure of a display substrate, in accordance with some embodiments;

FIG. 24 is a sectional view taken along the section line B8-B8 in FIG. 23;

FIG. 25 is a partial structural diagram of a display substrate after being subjected to pressure, in accordance with some embodiments;

FIG. 26 is a top view of another partial structure of a display substrate, in accordance with some embodiments;

FIG. 27 is an equivalent circuit diagram of an array substrate, in accordance with some embodiments;

FIG. 28 is a diagram showing a thickness of a liquid crystal cell after being subjected to an external force in a case where a spacer is not displaced, in accordance with some embodiments;

FIG. 29 is a diagram showing a thickness of a liquid crystal cell after being subjected to an external force in a case where a spacer is displaced, in accordance with some embodiments;

FIG. 30 is a diagram showing a deformation amount of a spacer after being displaced and subjected to an external force, in accordance with some embodiments;

FIG. 31 is a top view of yet another partial structure of a display substrate, in accordance with some embodiments;

FIG. 32 is a sectional view taken along the section line B9-B9 in FIG. 31;

FIG. 33 is another equivalent circuit diagram of an array substrate, in accordance with some embodiments;

FIG. 34 is a top view of yet another partial structure of a display substrate, in accordance with some embodiments;

FIG. 35 is a sectional view taken along the section line B10-B10 in FIG. 34;

FIG. 36 is a sectional view taken along the section line C1-C1 in FIG. 26;

FIG. 37 is a sectional view taken along the section line C2-C2 in FIG. 26;

FIG. 38 is a sectional view taken along the section line C3-C3 in FIG. 26; and

FIG. 39 is another sectional view taken along the section line C3-C3 in FIG. 26.

### DESCRIPTION OF THE INVENTION

The technical solutions in some embodiments of the present disclosure will be described clearly and completely with reference to the accompanying drawings. Obviously, the described embodiments are merely some but not all embodiments of the present disclosure. All other embodiments obtained by a person having ordinary skill in the art based on the embodiments of the present disclosure shall be included in the protection scope of the present disclosure.

Unless the context requires otherwise, throughout the description and claims, the term “comprise” and other forms thereof such as the third-person singular form “comprises” and the present participle form “comprising” are construed as an open and inclusive meaning, i.e., “including, but not limited to”. In the description of the specification, terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described may be included in any one or more embodiments or examples in any suitable manner.

In the present disclosure, terms such as “lower”, “below”, “above” and “upper” and the like are used to explain the relational association of components shown in the drawings. The terms may be relative concepts and described based on the directions shown in the drawings, or may be described based on the order in which the process steps are formed, but are not limited thereto.

Term “opposed to” means that a first element may be directly or indirectly opposed to a second element. In a case where a third element is interposed between the first element and the second element, the first element and the second element may be understood as being indirectly opposite to each other although still opposite to each other.

The terms “first” and “second” are used for descriptive purposes only, and are not to be construed as indicating or implying a relative importance or implicitly indicating the number of indicated technical features. Thus, a feature defined with “first” or “second” may explicitly or implicitly include one or more of the features. In the description of the embodiments of the present disclosure, the terms “a plurality of” “the plurality of” and “multiple” each mean two or more unless otherwise specified.

In the description of some embodiments, terms such as “coupled” and “connected” and their derivatives may be used. For example, the term “connected” may represent a fixed connection, or a detachable connection, or a one-piece connection; alternatively, the term “connected” may represent a direct connection, or an indirect connection through an intermediate medium. For example, the term “coupled” indicates that two or more components are in direct physical or electrical contact. The term “coupled” or “communicatively coupled” may also mean that two or more components are not in direct contact with each other but still cooperate or interact with each other. The embodiments disclosed herein are not necessarily limited to the content herein.

The phrase “at least one of A, B, and C” has the same meaning as the phrase “at least one of A, B, or C”, both including the following combinations of A, B, and C: only A, only B, only C, a combination of A and B, a combination of A and C, a combination of B and C, and a combination of A, B, and C.

The phrase “A and/or B” includes following three combinations: only A, only B, and a combination of A and B.

The phrase “applicable to” or “configured to” as used herein indicates an open and inclusive expression, which does not exclude apparatuses that are applicable to or configured to perform additional tasks or steps.

In addition, the use of the phrase “based on” is meant to be open and inclusive, since a process, step, calculation or other action that is “based on” one or more of the stated conditions or values may, in practice, be based on additional conditions or values exceeding those stated.

The term such as “about”, “substantially” or “approximately” as used herein includes a stated value and an average value within an acceptable range of deviation of a particular value determined by a person of ordinary skill in the art, considering measurement in question and errors associated with measurement of a particular quantity (i.e., limitations of a measurement system).

The term such as “parallel”, “perpendicular” or “equal” as used herein includes a stated case and a case similar to the stated case within an acceptable range of deviation determined by a person of ordinary skill in the art, considering measurement in question and errors associated with measurement of a particular quantity (i.e., limitations of a measurement system). For example, the term “parallel” includes absolute parallelism and approximate parallelism, and an acceptable range of deviation of the approximate parallelism may be, for example, a deviation within 5°; the term “perpendicular” includes absolute perpendicularity and approximate perpendicularity, and an acceptable range of deviation of the approximate perpendicularity may also be, for example, a deviation within 5°; and the term “equal” includes absolute equality and approximate equality, and an acceptable range of deviation of the approximate equality may be, for example, a difference between two equals being less than or equal to 5% of either of the two equals.

It will be understood that, in a case where a layer or an element is referred to as being on another layer or a substrate, it may be that the layer or the element is directly on the another layer or the substrate, or there may be a middle layer between the layer or the element and the another layer or the substrate.

Exemplary embodiments are described herein with reference to sectional views and/or plan views that are schematic illustrations of idealized embodiments. In the accompanying drawings, thicknesses of layers and sizes of regions are enlarged for clarity. Variations in shape with respect to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown to have a rectangular shape generally has a feature being curved. Therefore, the regions shown in the accompanying drawings are schematic in nature, and their shapes are not intended to show actual shapes of the regions in a device, and are not intended to limit the scope of the exemplary embodiments.

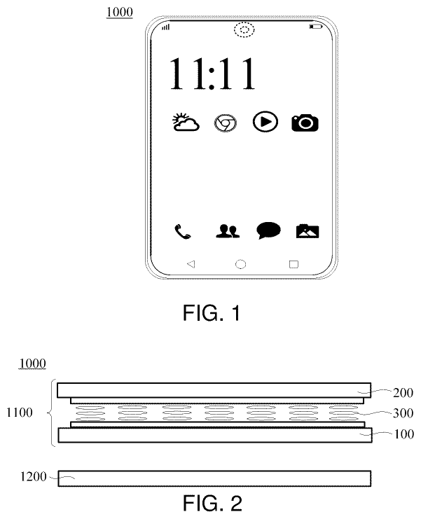

As shown in FIG. 1, some embodiments of the present disclosure provide a display device, and the display device 1000 is a product having a function of displaying images. For example, the display device 1000 may be any device that displays images whether in motion (such as a video) or fixed (such as a still image), and regardless of text or image.

For example, the display device 1000 may be any product or component having a display function, such as a television, a laptop computer, a tablet computer, a personal digital assistant (PDA), a mobile phone (cell phone), a watch, a clock, a calculator, a GPS receiver/navigator, a camera, a display of a camera view (e.g., a display of a rear view camera in a vehicle), a wearable device, an augmented reality (AR) device, a virtual reality (VR) device, a mixed reality (MR) device, a vehicle-mounted display, a flight display or the like.

In some embodiments, according to a light-emitting type of the display device 1000, the display device 1000 may be a liquid crystal display (LCD) device. According to a driving type and a form of the display device 1000, the display device 1000 may be a flat display device or a curved display device. According to a shape of the display device 1000, the display device 1000 may be rectangular or circular. Some embodiments of the present disclosure are schematically described below using a rectangular and planar liquid crystal display device as an example, but the implementation of the present disclosure is not limited thereto, and any other display device may also be considered as long as a same technical concept is applied.

In some embodiments, referring to FIG. 2, a display device 1000 includes a display substrate 1100 (also referred to as a display panel) and a driving circuit board (not shown in the figure). The driving circuit board includes driving circuits such as a timing controller (TCON), a power management chip (DC/DC), and an adjustable resistance voltage division circuit (for generating Vcom signal). The driving circuit board may further include other circuit structures, which will not be listed here. The driving circuit board is electrically connected to the display substrate 1100, and used for transmitting a control signal to the display substrate 1100, thereby driving the display substrate 1100 to implement image display. In addition, the display device 1000 may further include a touch structure, an under-screen camera, an under-screen fingerprint recognition sensor and the like, so that the display device 1000 is able to implement various functions such as touch control, taking pictures, video recording, or fingerprint recognition, which will not be listed here.

Continuing to refer to FIG. 2, in a case where the display device 1000 is a liquid crystal display device, the display device 1000 may further include a backlight source 1200 provided on a backlight side of the display substrate 1100. For example, the backlight source 1200 may be a direct-type backlight source or an edge-type backlight source, etc. The backlight source 1200 is used to provide a light source for the display substrate 1100. The display substrate 1100 includes a plurality of sub-pixels, each of the plurality of sub-pixels may adjust the amount of light passing through the display substrate 1100, thereby enabling each sub-pixel to display the same or different gray scales, so as to implement the purpose of image display.

Continuing to refer to FIG. 2, in a case where the display substrate 1100 is a liquid crystal display substrate, the display substrate 1100 may include an array substrate 100 and a color filter substrate 200 that are disposed opposed to each other, and a liquid crystal layer 300 disposed between the array substrate 100 and the color filter substrate 200. The color filter substrate 200 may further be referred to as an opposing substrate or a packaging substrate. Of course, the structure of the display substrate 1100 is not limited thereto, and the display substrate 1100 may further include other structures as long as the same technical concept is adopted. For example, the display substrate 1100 may further include a first alignment film (not shown in the figure) disposed on a side of the array substrate 100 proximate to the liquid crystal layer 300, and a second alignment film (not shown in the figure) disposed on a side of the color filter substrate 200 proximate to the liquid crystal layer 300.

The array substrate 100 may be an advanced super dimension switch (ADS) type or a high-advanced dimension switch (HADS) type with a high aperture ratio. ADS technology may form multi-dimensional electric fields through an electric field generated by an edge of a slit electrode in a same plane and an electric field generated between a slit electrode layer and a plate electrode layer, so that liquid crystal molecules in all directions located between the slit electrode and located directly above the slit electrode in a liquid crystal cell may be rotated, thereby improving working efficiency of liquid crystals and increasing a light transmission efficiency. In addition, ADS technology has advantages of high resolution, high transmittance, low power consumption, wide viewing angle, high aperture ratio, low color difference, and no push mura. In addition, the array substrate 100 may include a display region and a peripheral region disposed around the display region. The display region may include a plurality of pixel circuits, a plurality of pixel electrodes and a plurality of first electrodes, and the peripheral region may include, for example, a gate driver on array (GOA for short).

The color filter substrate 200 may include a filter portion and a black matrix. The filter portion is used to filter the light incident on the color filter substrate 200, so that each sub-pixel emits light of a color (e.g., red, green or blue). In this way, different sub-pixels may emit light of the same or different colors, thereby enabling the display substrate 1100 to implement color display. The black matrix is used to cover transistors and signal lines on the array substrate, so as to improve the contrast of the display substrate.

In a liquid crystal display device, the transmittance of the display substrate 1100 is an important indicator. Improving the transmittance of the display substrate 1100 may not only improve the brightness of the display device, but also reduce the power consumption of the backlight source 1200 of the display device, thereby reducing the overall power consumption of the display device. A conventional ADS liquid crystal display substrate includes a plurality of signal lines on the array substrate and a black matrix on the color filter substrate. An orthogonal projection of the black matrix on the array substrate covers the plurality of signal lines, so as to reduce light leakage in the signal lines and regions surrounding the signal lines. However, due to a size of the black matrix in the color filter substrate, the transmittance of the display substrate is low.

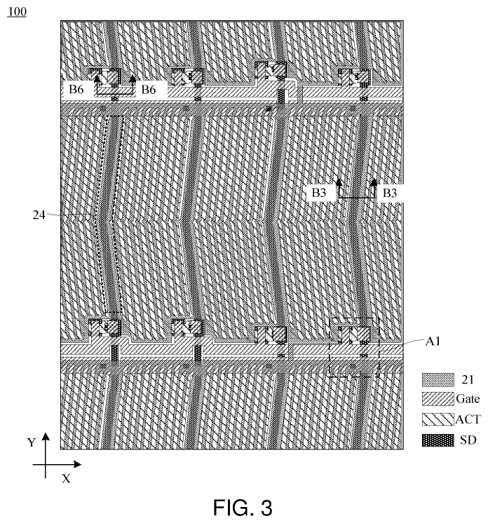

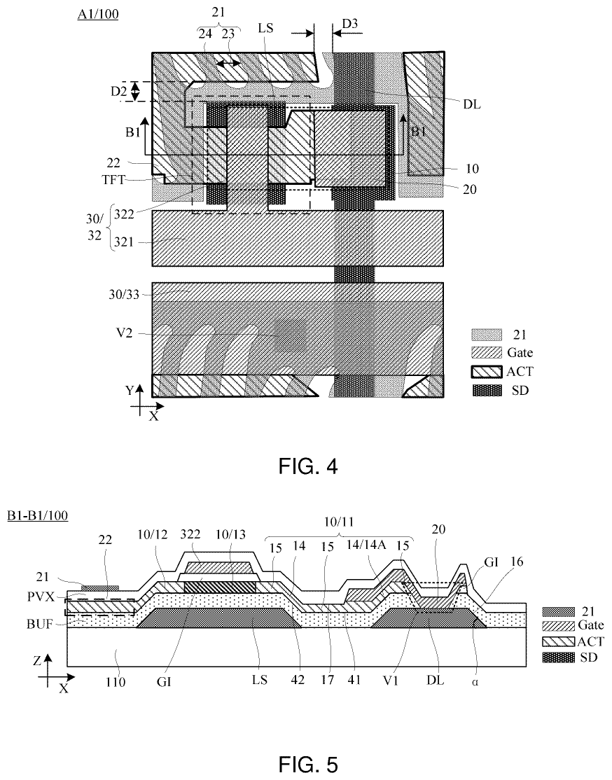

FIG. 3 is a partial structural diagram of the display region in a case where the array substrate does not include a planarization layer. FIG. 4 is a partial structural diagram of a region where a thin film transistor of the array substrate is located; and FIG. 5 is a cross-sectional structural diagram of a region where the thin film transistor is located in a case where the array substrate does not include the planarization layer.

Referring to FIGS. 3, 4 and 5, in order to improve the transmittance of the display substrate, some embodiments of the present disclosure provide an array substrate 100. The array substrate 100 includes a first substrate 110 and a first conductive layer SD, a first insulating layer BUF, a semiconductor layer ACT and a connecting electrode 20 that are sequentially disposed in a direction away from the first substrate 110. In addition, the array substrate 100 further includes a first via hole V1 at least penetrating the first insulating layer BUF.

For example, the first substrate 110 may be a rigid substrate. The above-mentioned rigid substrate may be, for example, a glass substrate or a polymethyl methacrylate (PMMA) substrate. The first substrate 110 may further be a flexible substrate. For example, the above-mentioned flexible substrate may be a polyethylene terephthalate (PET) substrate, a polyimide (PI) substrate, or a polyethylene naphthalate two formal acid glycol ester (PEN) substrate. For example, the first substrate 110 may be a transparent substrate, so that the light emitted by the backlight source may pass through the first substrate 110, which is conducive to improving the transmittance of the array substrate 100.

The first conductive layer SD is disposed on a side of the first substrate 110, and the first conductive layer SD includes at least one first signal line DL and a first pattern LS that are distributed at intervals. In some embodiments of the present disclosure, the first signal line DL and the first pattern LS include a same material and are disposed in a same layer. For example, the first pattern LS and the first signal line DL are formed by using a same mask and/or a same material in a same patterning process.

The first signal line DL and the first pattern LS are both disposed on a side of the semiconductor layer ACT proximate to the first substrate 110. In this way, it is conducive to reducing a parasitic capacitance between the first signal line DL and other structures (e.g., a first electrode 21 and a second electrode 22), thereby improving a pixel density and a refresh rate of the array substrate 100, and it is conducive to reducing the power consumption of the first signal line DL and reduce the overall power consumption of the array substrate 100. In addition, it is conducive to increasing a distance between the first signal line DL and the liquid crystal layer. It may further reduce influence of an electric field generated by the first signal line DL on the liquid crystal molecules of the liquid crystal layer, reduce an area of the light leakage region caused by the first signal line DL, and reduce the size of the black matrix used to block the first signal line DL, thereby increasing the aperture ratio of the display substrate and improving the transmittance of the display substrate.

For example, the first signal line DL is disposed on the first substrate 110, and the first signal line DL may be a data signal line configured to transmit a data signal. Of course, in some other examples, the first signal line DL may further be used to transmit other signals, as long as the same technical concept is adopted. The first pattern LS may be a light shielding pattern, and may be configured to shield a channel structure 13 of the semiconductor layer ACT, so as to reduce the light directed toward the channel structure 13 and reduce a risk of the thin film transistor drifting due to the illumination of the backlight source. For example, an orthogonal projection of the first pattern LS on the first substrate 110 overlaps at least partially (e.g., at least 50%, at least 60%, at least 70%, at least 80%, at least 90%, at least 95%, at least 98%, at least 99% or 100%) with an orthogonal projection of the channel structure 13 on the first substrate 110.

In some embodiments, a material of the first conductive layer SD may include a conductive material, and the conductive material may include a metal material. For example, the metal material may include one or more of metal titanium, aluminum, copper, molybdenum, niobium, nickel and alloys thereof. Or, the first conductive layer SD may further be a metal stacked structure. For example, the first conductive layer SD may include one of a titanium-aluminum-titanium (Ti/Al/Ti) stacked structure, a molybdenum-aluminum (Mo/Al) stacked structure, a molybdenum-aluminum-molybdenum (Mo/Al/Mo) stacked structure, a molybdenum-niobium-titanium (MoNb/Ti) stacked structure, a molybdenum-niobium-titanium-copper (MoNb/Ti/Cu) stacked structure, a molybdenum-niobium-copper (MoNb/Cu) stacked structure, a molybdenum-nickel-titanium-copper (MTD/Cu) stacked structure, a molybdenum-niobium-copper-molybdenum-titanium-nickel (MoNb/Cu/MTD) stacked structure, a molybdenum-nickel-titanium-copper-molybdenum-nickel-titanium (MTD/Cu/MTD) stacked structure, a molybdenum-neodymium-copper stacked structure, a MoNb-copper-MoNb stacked structure, and an AINb-molybdenum-AINd stacked structure, or a combination thereof. Of course, some embodiments of the present disclosure are not limited thereto, and the first conductive layer SD may further be made of any other suitable metal or metal stacked structure. In addition, a thickness of the first conductive layer SD may be 1000 Å (angstroms; 1 Å=10⁻¹⁰ m) to 10000 Å. For example, the thickness of the first conductive layer SD may be 1000 Å,4000 Å, 8000 Å or 10000 Å, etc., which will not be listed one by one in the embodiments of the present disclosure.

The first insulating layer BUF is disposed on a side of the first conductive layer SD away from the first substrate 110, and the first insulating layer BUF may include an insulating material. The first insulating layer BUF may be used to cover at least a portion of the first signal line DL, so as to prevent the first signal line DL from being short-circuited with a conductive structure (e.g., the second signal line 32) disposed on an upper side of the first signal line DL.

For example, a material of the first insulating layer BUF may include silicon oxide compound (SiOx, x>0). In some embodiments, a value of x may be 1 or 2. The material of the first insulating layer BUF may also include silicon nitride compound (SiNy, y>0). In some embodiments, a value of y may be 1 to 2, such as SIN and SIN1.33. The first insulating layer BUF may be a single layer or a stacked layer structure. In some embodiments, the first insulating layer BUF is a stacked layer structure including the silicon oxide compound and the silicon nitride compound. In addition, a thickness of the first insulating layer BUF may be in a range from 100 nm to 700 nm. For example, the thickness of the first insulating layer BUF may be 100 nm, 300 nm, 550 nm or 700 nm, etc., which will not be listed one by one in the embodiments of the present disclosure.

The first via hole V1 at least penetrates the first insulating layer BUF and exposes at least a portion of the first signal line DL, which facilitates connecting the first signal line DL to the semiconductor layer ACT (a first portion 11). The first portion 11 is configured to be connected to the first signal line DL through the first via hole V1, so that the first signal line DL may transmit a data signal to the first portion 11.

The semiconductor layer ACT is located on a side of the first insulation layer BUF away from the first substrate 110. The semiconductor layer ACT includes a plurality of semiconductor patterns 10, and one of the plurality of semiconductor patterns 10 is configured to form a thin film transistor (TFT). That is, a thin film transistor may include a semiconductor pattern 10. FIGS. 4 and 5 both exemplarily show a thin film transistor and a semiconductor pattern 10. The semiconductor pattern 10 may include the first portion 11, a second portion 12, and the channel structure 13 between the first portion 11 and the second portion 12. The channel structure 13 is configured to form a channel structure of a TFT. One of the first portion 11 and the second portion 12 is configured to form a source (or a source connecting region) of the TFT, and another of the first portion 11 and the second portion 12 is configured to form a drain (or a drain connecting region) of the TFT.

In some embodiments, an orthogonal projection of the first portion 11 on the first substrate 110 partially overlaps with an orthogonal projection of the first signal line DL on the first substrate 110. In this way, during a manufacturing process of the array substrate 100 (see below), it may reduce difficulty of forming the first via hole V1 with a great depth between the first portion 11 and the first signal line DL, thereby reducing climbing difficulty of the connecting electrode 20 on a side wall of the first via hole V1, which is conducive to improving the continuity of the connecting electrode 20 in the first via hole V1 and ensuring the connection stability between the first portion 11 and the first signal line DL.

The orthogonal projection of the channel structure 13 on the first substrate 110 is within a range of the orthogonal projection of the first pattern LS on the first substrate 110. Based on this, the first pattern LS may block the light emitted from the backlight source toward the channel structure 13 to a great extent, thereby reducing the risk of threshold voltage drift of the channel structure 13 under lighting conditions.

For example, as shown in FIG. 4, the orthogonal projection of the first pattern LS on the first substrate 110 completely covers the orthogonal projection of the channel structure 13 on the first substrate 110, and at least part of a boundary (an entire boundary of the first pattern LS in FIG. 4) of the orthogonal projection of the first pattern LS on the first substrate 110 does not overlap with a boundary of the orthogonal projection of the channel structure 13 on the first substrate 110. That is, an area of the first pattern LS is greater than an area of the channel structure 13, so that the first pattern LS may block as much light as possible from being directed to the channel structure 13.

In some embodiments, the semiconductor layer ACT includes a metal oxide material having a Hall mobility in a range from 10 cm²/V.s to 30 cm²/V.s. In some embodiments, the semiconductor layer ACT includes a metal oxide material having a Hall mobility greater than or equal to 30 cm²/V.s.

For example, the semiconductor layer ACT may be manufactured by using various appropriate semiconductor materials and various appropriate manufacturing methods, or in other words, the material of the semiconductor layer ACT may include at least one of the various appropriate semiconductor materials. In some embodiments, the semiconductor material includes M1OaNb. M1 is a single metal or a combination of multiple metals, a is greater than 0 (e.g., a>0), and b is greater than or equal to 0 (e.g., b≥0). O represents oxygen, and N represents nitrogen. That is, the semiconductor material is a metal oxide material or a metal oxynitride material. Appropriate metal oxide materials include, but are not limited to one or more of indium gallium zinc oxide (IGZO), indium gallium tin oxide (IGTO), indium tin zinc oxide (ITZO), indium gallium oxide (IGO), indium gallium zinc tin oxide (IGZTO), indium zinc oxide (IZO), zinc tin oxide (ZTO), indium-free metal oxide (In-free OS), rare earth-doped oxide (Ln-OS, such as rare earth element-doped IGZO/IZO), zinc oxide (ZnO), gallium oxide (GaO), indium oxide (InO), HfInZnO (HIZO), ZnO: F, In₂O₃: Sn, In₂O₃: Mo, Cd₂SnO₄, ZnO: Al, TiO₂: Nb and Cd—Sn—O. The material of the semiconductor layer ACT may be in an amorphous state, a partially crystalline state, a monocrystalline state or a polycrystalline state, and may also be a single-layer or a multi-layer structure.

Appropriate metal oxynitride materials include, but are not limited to: zinc oxynitride, indium oxynitride, gallium oxynitride, tin oxynitride, cadmium oxynitride, aluminum oxynitride, germanium oxynitride, titanium oxynitride, silicon oxynitride, or combinations thereof. In an example, the material of the semiconductor layer ACT includes indium gallium zinc oxide (IGZO).

In some embodiments, the first portion 11, the second portion 12 and the channel structure 13 are an integral structure, and materials of the channel structure 13, and the first portion 11 and the second portion 12 all include M1OaNb. The first portion 11 and the second portion 12 are different from the channel structure 13 in that the first portion 11 and the second portion 12 are subjected to a process (e.g., a conductive process) to make them more conductive. The conductivity of the channel structure 13 is different from the conductivity of the first portion 11, and the conductivity of the channel structure 13 is different from the conductivity of the second portion 12.

For example, the channel structure 13 may include a semiconductor material, and the second portion 12 and the first portion 11 may include a doped semiconductor material. In this way, the second portion 12 and the first portion 11 may form a conductor, and the channel structure 13 may form a semiconductor.

In an example, in a case where the materials of the channel structure 13, the first portion 11, and the second portion 12 all include M1OaNb, the M1OaNb in the first portion 11 and the second portion 12 are subjected to a lightly doping process (e.g., a lightly doping ion implantation process). In another example, in a case where the materials of the channel structure 13, the first portion 11, and the second portion 12 include M1OaNb, the M1OaNb in the first portion 11 and the second portion 12 are subjected to an annealing process. In yet another example, in a case where the material of the channel structure 13, the first portion 11, or the second portion 12 includes M1OaNb, the M1OaNb in the first portion 11 or the second portion 12 is subjected to an oxide replenishment process. For example, a doping concentration in a range from about 1×10¹⁵ atoms/cm³ to about 1×10²⁰ atoms/cm³ may be used. For example, the lightly doping process may be performed using doping concentrations ranging about 1×10¹⁵ atoms/cm³ to about 1×10¹⁶ atoms/cm³, about 1×10¹⁶ atoms/cm³ to about 1×10¹⁷ atoms/cm³, about 1×10¹⁷ atoms/cm³ to about 1×10¹⁸ atoms/cm³, about 1×10¹⁸ atoms/cm³ to about 1×10²⁰ atoms/cm³, and about 1×10¹⁹ atoms/cm³ to about 1×10²⁰ atoms/cm³. For example, the lightly doping process is performed by using an N-type dopant to enhance conductivity. For example, the N-type dopant may include elements of Group VA of the periodic table, which include but not limited to nitrogen (N), phosphorus (P), arsenic (As), antimony (Sb), and bismuth (Bi). The lightly doping process may further be performed by using protective gas elements such as argon (Ar), helium (He), oxygen (O), hydrogen (H), or fluorine (F).

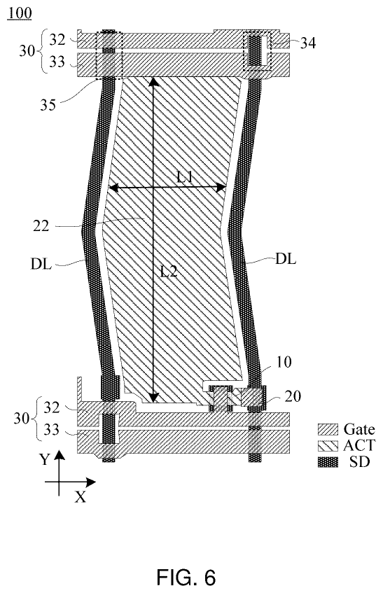

FIG. 6 is a structural diagram of the array substrate 100 after the first electrode 21 is removed based on FIG. 3.

In some embodiments, referring to FIGS. 5 and 6, the semiconductor layer ACT further includes a second electrode 22. The second electrode 22 is connected to the second portion 12 and is integrally disposed with the second portion 12. The second electrode 22 is disposed on a same layer as the semiconductor pattern 10, which is conducive to simplifying the manufacturing process of the array substrate 100 (a number of masks of the array substrate 100 may be reduced to six), so as to reduce the thickness and manufacturing cost of the array substrate 100, and is conducive to improving the light transmittance of the array substrate.

For example, the second electrode 22 may be a pixel electrode of the array substrate 100. A second electrode 22 is electrically connected to a thin film transistor (i.e., the second portion 12 of the semiconductor pattern 10) and is configured to receive the data signal transmitted by the first signal line DL.

For example, the second electrode 22 includes the same material and is manufactured in the same layer as the first portion 11 and the second portion 12. In order to improve the conductivity of the second electrode 22, the second electrode 22 may adopt the same conductive process as the first portion 11 and the second portion 12, so that the conductivity of the second electrode 22 is equivalent to that of the first portion 11 and the second portion 12, and is greater than the conductive line of the channel structure 13. The conductive process that may be selected for the second electrode 22 refers to the conductive process that may be adopted for forming the above-mentioned first portion 11 and second portion 12, and will not be repeated here.

In addition, in order to improve the transmittance of the array substrate 100, the second electrode 22 may further be manufactured by a transparent conductive material. The transparent conductive material refers to a conductive material whose light transmittance is greater than a first threshold. The first threshold may be, for example, 80%, 85%, 90%, 95% or other appropriate values, which are not listed here one by one. That is, the material of the semiconductor layer ACT is a transparent semiconductor material, and the transparent semiconductor material includes one or more of the semiconductor materials mentioned above, which will not be repeated here.

In some embodiments, referring to FIG. 6, a dimension L1 of the second electrode 22 along a first direction X is less than or equal to 1000 μm, and/or a dimension L2 of the second electrode 22 along a second direction Y is less than or equal to 1000 μm. In this way, it is conducive to improving the uniformity of the conductive treatment of the second electrode 22 during the conductive process. That is, the conductivity of various positions of the second electrode 22 may be made substantially the same. And, it is conducive to improving the conductivity of the second electrode 22.

For example, the dimension L1 of the second electrode 22 along the first direction X may be 300 μm, 600 μm, 750 μm, 900 μm or 1000 μm, etc. ; the dimension L2 of the second electrode 22 along the second direction Y may be 400 μm, 600 μm, 800 μm, 950 μm or 1000 μm, etc., which are not listed one by one in the embodiments of the present disclosure. The dimension L1 of the second electrode 22 along the first direction X and the dimension L2 of the second electrode 22 along the second direction Y may be equal, or the dimension L1 of the second electrode 22 along the first direction X and the dimension L2 of the second electrode 22 along the second direction Y may be unequal. For example, the dimension L2 of the second electrode 22 along the second direction Y is greater than a dimension L1 of the second electrode 22 along the first direction X, so that the second electrode 22 may form a substantially rectangular structure.

In some embodiments, the first insulating layer BUF is an inorganic insulating layer, which is generally formed by a thin film deposition process. Referring to FIG. 5, the first insulating layer BUF may be directly disposed on the first conductive layer SD. For example, the first insulating layer BUF is in direct contact with the first conductive layer SD. In this case, the first insulating layer BUF includes a first groove portion 41 that is concave (e.g., concave from top to bottom in FIG. 5) in a direction proximate to the first substrate 110, and at least a portion of the first groove portion 41 is located between the first signal line DL and the first pattern LS. That is, a surface of the first insulating layer BUF has an undulating morphology that is adapted to a morphology of a surface of the first conductive layer SD away from the first substrate 110. In this case, it is conducive to simplifying the manufacturing process of the array substrate 100 and reducing the manufacturing difficulty and manufacturing cost of the array substrate 100.

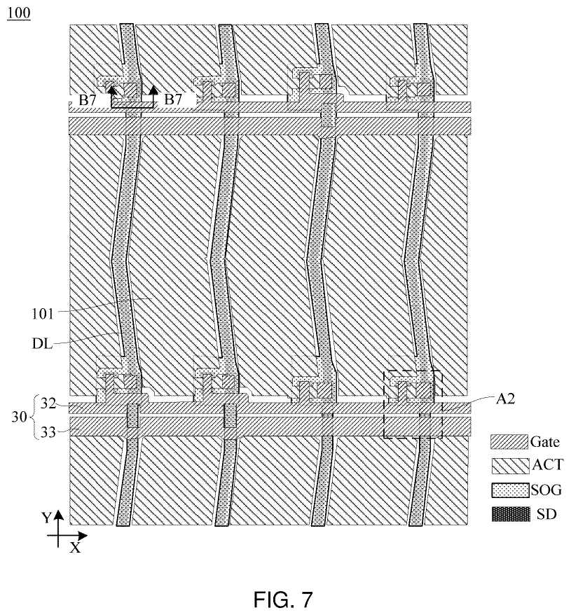

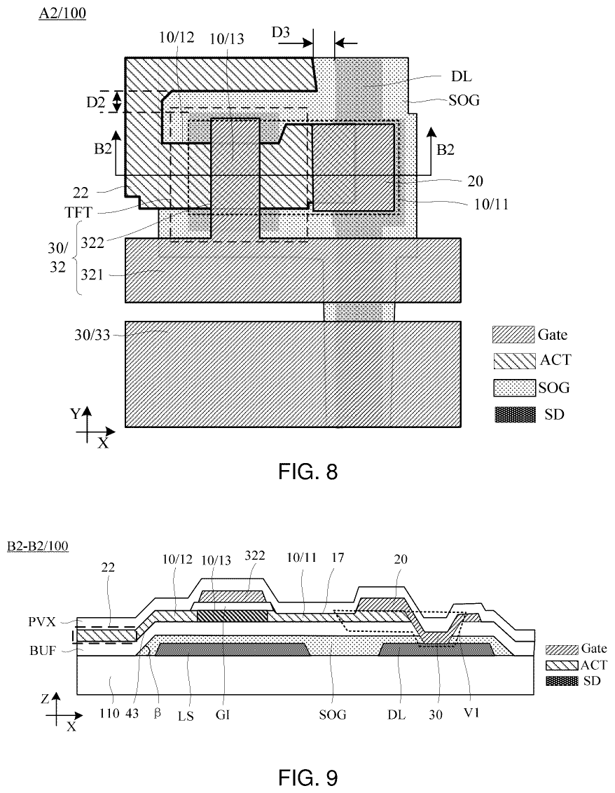

FIG. 7 is a partial structural diagram of the display region in a case where the array substrate includes the planarization layer; FIG. 8 is an enlarged partial view of the position of the thin film transistor in a case where the array substrate includes the planarization layer; and FIG. 9 is a cross-sectional structural diagram of the thin film transistor in a case where the array substrate includes the planarization layer.

In some other embodiments, referring to FIGS. 7, 8 and 9, the array substrate 100 further includes a planarization layer SOG. The planarization layer SOG is located between the first conductive layer SD and the first insulating layer BUF, and a surface of the planarization layer SOG away from the first substrate 110 is a flat surface. For example, an orthogonal projection of the planarization layer SOG on the first substrate 110 at least covers an orthogonal projection of the first conductive layer SD on the first substrate 110. That is, the planarization layer SOG at least covers the first signal line DL and the first pattern LS. In this way, it is conducive to improving the flatness of the position of the first insulating layer BUF covering the first conductive layer SD, and further improving the flatness of the overlapping position of the semiconductor layer ACT and the first conductive layer SD. Therefore, the risk of uneven thickness or even local fracture of the semiconductor layer ACT due to height difference on a surface where the semiconductor layer ACT is located may be reduced, and the performance of the semiconductor layer ACT may be improved.

For example, the planarization layer SOG may fill a space between the first signal line DL and the first pattern LS, so that a surface of a portion of the first insulating layer BUF between the first signal line DL and the first pattern LS and away from the first substrate 110 is flat, which is conducive to reducing the uneven thickness of the first portion 11 in the region between the first signal line DL and the first pattern LS, improving the uniformity of the thickness of the first portion 11, and thereby improving the connection reliability between the first portion 11 and the first signal line DL.

For example, the planarization layer SOG may be an organic insulating layer. For example, the material of the planarization layer SOG may be a silicon on glass (SOG for short) material.

Referring to FIGS. 5 and 9, the array substrate 100 further includes a second insulating layer GI. The second insulating layer GI is located at a side of the semiconductor layer ACT away from the first insulating layer BUF. For example, the second insulating layer GI is located between the semiconductor layer ACT and the connecting electrode 20.

A material of the second insulating layer GI may include an insulating material, and the insulating material may be, for example, silicon oxide. Of course, the second insulating layer GI is not limited thereto, and any other appropriate material may be used. The second insulation layer GI may be a single-layer or a multi-layer structure. In addition, a thickness of the second insulation layer GI may be in a range from 600 Å to 2000 Å. For example, the thickness of the second insulation layer GI is 600 Å, 1000 Å, 1500 Å, or 2000 Å nm, etc., which are not listed one by one in the embodiments of the present disclosure.

In some embodiments, referring to FIGS. 4 and 5 or referring to FIGS. 8 and 9, the array substrate 100 further includes a connecting electrode 20. The connecting electrode 20 is located on a side of the semiconductor layer ACT away from the first substrate 110. At least a portion of the connecting electrode 20 is located in the first via hole V1, and the connecting electrode 20 is electrically connected to the first signal line DL and the first portion 11, thereby electrically connecting the first signal line DL and the first portion 11. That is, the first portion 11 is configured to be electrically connected to the first signal line DL through the connecting electrode 20. The first portion 11 is indirectly electrically connected to the first signal line DL through the connecting electrode 20.

In addition, referring to FIG. 7, the array substrate 100 further includes a plurality of signal line groups 30. The plurality of signal line groups 30 are arranged at intervals along the second direction Y, and all of the plurality of signal line groups 30 extend along the first direction X. A plurality of first signal lines DL and the plurality of signal line groups 30 intersect each other to form a grid structure, and each grid in the grid structure defines a pixel region 101.

The pixel region 101 may be a red pixel region, a green pixel region, or a blue pixel region. Each pixel region 101 is controlled by one of first signal lines DL surrounding the pixel region 101 and one of signal line groups 30 surrounding the pixel region 101. For example, the first signal line D L transmits the data signal to the second electrode 22 of the pixel region 101 under control of the signal line group 30. An electric field may be generated between the second electrode 22 and the first electrode 21, so as to drive the liquid crystal molecules in the liquid crystal layer to deflect. A deflection angle of the liquid crystal molecules may control a polarization direction of the light passing through the pixel region 101, and may be cooperated with a polarizer to implement different gray scale displays.

FIG. 7 only exemplarily shows partial regions of two signal line groups 30 and four first signal lines DL in the array substrate. In some embodiments of the present disclosure, a length direction (e.g., an extending direction) of the signal line group 30 is taken as the first direction X, and a length direction (e.g., an extending direction) of the first signal line DL is taken as the second direction Y. The first direction X is intersected with the second direction Y. For example, the first direction X and the second direction Y are perpendicular to each other. At at least one overlapping position of the orthogonal projection of the signal line group 30 and the first signal line DL, the signal line group 30 may extend along the first direction X. The overlapping position of the orthogonal projection is used to form a main spacer region of the spacer. The at least one overlapping position of the orthogonal projection of the signal line group 30 and the first signal line DL, the signal line group 30 may be a fold line, and the fold line may form a recess on the signal line group 30. The recess is recessed toward a side away from the center of the signal line group 30 along the second direction Y, and is configured to form a secondary spacer region. The shape and structure of the signal line group 30 will be described below.

In some embodiments, referring to FIGS. 4 and 8, the signal line group 30 may include one or more second signal line 32. For example, the second signal line 32 is configured to transmit a gate signal to the thin film transistor TFT. The second signal line 32 includes a main extending portion 321 and a gate portion 322. The main extending portion 321 extends along the first direction X, and the gate portion 322 protrudes from the main extending portion 321 along the second direction Y to form a gate of the thin film transistor. The main extending portion 321 and the gate portion 322 include a same material and are located at a same layer. For example, the main extending portion 321 and the gate portion 322 are an integral structure. In this case, the gate portion 322 may be regarded as a branch structure extending outward (e.g., perpendicular to the extending direction X of the second signal line 32) of the main extending portion 321.

Referring to FIGS. 8 and 9, a size of the gate portion 322 may define the area of the channel structure 13. For example, the orthogonal projection of the channel structure 13 on the first substrate 110 is within a range of an orthogonal projection of the gate portion 322 on the first substrate 110. That is, a portion where the orthogonal projection of the semiconductor pattern 10 on the first substrate 110 overlaps with the orthogonal projection of the gate portion 322 on the first substrate 110 is the channel structure 13. A portion of the semiconductor pattern 10 located at a side of the channel structure 13 proximate to the first via hole V1 is the first portion 11, and a portion of the semiconductor pattern 10 located at a side of the channel structure 13 away from the first via hole V1 is the second portion 12.

A thin film transistor may include a gate portion 322, a first portion 11, a second portion 12, and a channel structure 13. One of the first portion 11 and the second portion 12 forms a source connecting region of the thin film transistor (for example, the first portion 11 forms the source connecting region), and another of the first portion 11 and the second portion 12 forms a drain connecting region of the thin film transistor (for example, the second portion 12 forms the drain connecting region), the channel structure 13 forms a channel of the thin film transistor, and the gate portion 322 forms a gate of the thin film transistor. The thin film transistor is turned on or turned off under control of the gate portion 322. That is, the channel structure 13 electrically connects the first portion 11 and the second portion 12 under the control of the gate portion 322 (the thin film transistor is turned on), or the channel structure 13 electrically insulates the first portion 11 and the second portion 12 under the control of the gate portion 322 (the thin film transistor is turned off).

In some embodiments, the first pattern LS may further be used to transmit an electrical signal. In this case, the first pattern LS may be electrically connected to the second signal line 32. The first pattern LS constitutes the gate of a thin film transistor, and the thin film transistor forms a dual-gate structure. Alternatively, in some other embodiments, the first pattern LS may not be used to transmit the electrical signal. For example, the first pattern LS is electrically insulated from the second signal line 32. In this case, the thin film transistor has a top gate structure including the gate portion 322.

In some embodiments, referring to FIG. 9, the connecting electrode 20 and the signal line group 30 include a same material and are disposed in a same layer. Or, the connecting electrode 20 and the second signal line 32 include a same material and are disposed in a same layer. For example, the connecting electrode 20 and the signal line group 30 are formed by using a same mask and/or a same material in a same patterning process. Compared with using additional film layers and processes to manufacture the connecting electrode 20, the connecting electrode 20 and the signal line group 30 include the same material and are disposed in the same layer, which is conducive to simplifying the manufacturing process of the array substrate 100 and reduce the manufacturing cost of the array substrate 100. For example, in some embodiments of the present disclosure, the film layer where the connecting electrode 20 and the signal line group 30 are located is a gate conductive layer Gate.

In some embodiments, referring to FIG. 9, the first portion 11, the channel structure 13, and the second portion 12 are disposed substantially along a straight line. That is, the first portion 11, the channel structure 13, and the second portion 12 extend substantially in a straight line. In this way, it is conducive to reducing a width of the thin film transistor (i.e., a dimension along the second direction Y), thereby reducing an area of the black matrix on the color filter substrate. In addition, it is also conducive to improving the aperture ratio of the display substrate, thereby improving the transmittance of the display substrate.

It will be noted that an orthogonal projection of the black matrix of the color filter substrate on the array substrate at least covers the thin film transistor. The black matrix may reduce the ambient light directed to the thin film transistor, thereby reducing the reflection of the ambient light by the thin film transistor and improving the display quality of the display substrate.

In some embodiments, referring to FIG. 9, the first portion 11, the channel structure 13, and the second portion 12 extend approximately along the first direction X. That is, an arrangement direction of the first portion 11, the channel structure 13, and the second portion 12 is approximately parallel to the extending direction of the second signal line 32, and the first portion 11, the channel structure 13, and the second portion 12 are disposed proximate to the second signal line 32. In this way, the space occupied by the thin film transistor and the second signal line 32 in the second direction Y may be greatly reduced, and the area of the black matrix on the color filter substrate may be greatly reduced, which is conducive to improving the aperture ratio of the display substrate and further improving the transmittance of the display substrate.

In some embodiments, the material of the connecting electrode 20 and the signal line group 30 may include a metal material. For example, the connecting electrode 20 and the signal line group 30 may be a metal stacked structure. The metal stack structure may refer to the metal stack structure of the first signal line DL mentioned above, which will not be repeated here. The material of the connecting electrode 20 and the signal line group 30 may be the same as that of the first signal line DL, or the material of the connecting electrode 20 and the signal line group 30 may be different from that of the first signal line DL. In addition, a thickness of the connecting electrode 20 and a thickness of the signal line group 30 may be in a range from 200 nm to 1200 nm. For example, the thickness of the connecting electrode 20 and the signal line group 30 may be 200 nm, 500 nm, 950 nm or 1200 nm, etc., which will not be listed one by one in the embodiments of the present disclosure.

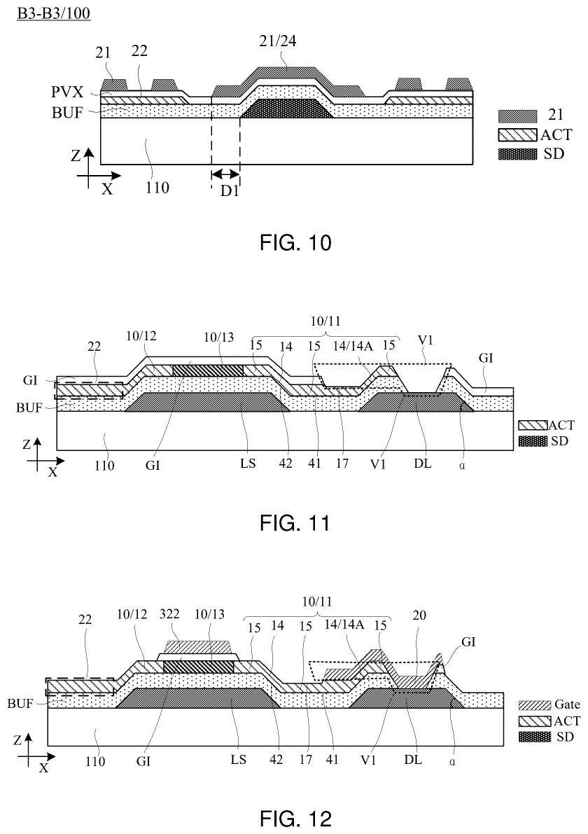

In some embodiments, referring to FIGS. 3 and 10, the array substrate further includes a first electrode 21. The first electrode 21 is disposed on a side of a film layer where the connecting electrode 20 is located away from the first substrate 110, and an orthogonal projection of the first electrode 21 on the first substrate 110 covers the orthogonal projection of the first signal line DL on the first substrate 110. Based on this, the first electrode 21 may shield the influence of the electric field generated by the first signal line DL on the liquid crystal layer, reduce an area of the region of the liquid crystal layer where light leakage occurs due to the voltage fluctuation of the first signal line DL, which is conducive to reducing the area of the black matrix on the color filter substrate.

For example, the first electrode 21 may be a common electrode of the array substrate 100. In this way, in a case where the array substrate 100 is operating, the first electrode 21 is connected to a constant voltage signal terminal, and the voltage on the first electrode 21 will not be affected by the voltage fluctuation of the first signal line DL, thereby reducing the risk of voltage fluctuation on the first electrode 21.

In some embodiments, as shown in FIGS. 3 and 4, the first electrode 21 further covers at least a portion of the pixel region 101. For example, the first electrode 21 includes a plurality of slits 23, so that the first electrode 21 forms a plurality of slit electrodes, which facilitates the array substrate 100 to form an ADS type array substrate.

The material of the first electrode 21 may include, for example, a transparent conductive material, so that the light emitted from the backlight source is capable of passing through the first electrode 21. The transparent conductive material includes but is not limited to at least one of indium tin oxide (ITO), indium zinc oxide (IZO), zinc oxide (ZnO) and IGZO. In addition, a thickness of the first electrode 21 may be in a range from 40 nm to 135 nm. For example, the thickness of the first electrode 21 may be 40 nm, 80 nm, 100 nm or 135 nm, etc., which will not be listed one by one in the embodiments of the present disclosure.

In some embodiments, referring to FIGS. 3 and 10, the first electrode 21 includes a first extending segment 24. An extending direction of the first extending segment 24 is the same as an extending direction of the first signal line DL. An orthogonal projection of the first extending segment 24 on the first substrate 110 covers the orthogonal projection of the first signal line DL on the first substrate 110, and there is a first interval D1 between a boundary of the orthogonal projection of the first extending segment 24 on the first substrate 110 and a boundary of the orthogonal projection of the first signal line DL on the first substrate 110. The first interval D1 is in a range from 2 μm to 5 μm, so that the covering effect of the first extending segment 24 on the first signal line DL may be greatly improved, the shielding effect of the first extending segment 24 on the electric field of the first signal line DL may be improved, and the influence of the electric field generated by the first signal line DL on the liquid crystal layer may be greatly reduced, which is conducive to reducing a width of a portion of the black matrix on the color filter substrate covering the first signal line DL, thereby improving the aperture ratio of the display substrate. For example, the first interval D1 may be 2 μm, 3 μm, 4 μm, 4.5 μm, or 5 μm, etc., which will not be listed one by one in the embodiments of the present disclosure.

In some embodiments, referring to FIGS. 4 and 8, there is a second interval D2 between an orthogonal projection of the second electrode 22 on the first substrate 110 and the orthogonal projection of the first pattern LS on the first substrate 110. The second interval D2 is conducive to reducing a parasitic capacitance between the second electrode 22 and the first pattern LS, and is conducive to reducing the risk of signal interference between the gate portion 322 and the second electrode 22.

Continuing to refer to FIGS. 4 and 8, there is a third interval D3 between the orthogonal projection of the second electrode 22 on the first substrate 110 and the orthogonal projection of the first signal line DL on the first substrate 110. The third interval D3 is conducive to increasing an interval between the second electrode 22 and the first signal line DL, reducing the risk of short circuit between the second electrode 22 and the first signal line DL, and reducing the magnitude of the parasitic capacitance generated between the second electrode 22 and the first signal line DL, thereby reducing the signal crosstalk between the second electrode 22 and the first signal line DL. For example, it may reduce the amplitude of the voltage fluctuation on the second electrode 22 caused by the voltage fluctuation of the first signal line DL.

In some embodiments, referring to FIGS. 4 and 5, in a case where the first insulating layer BUF is directly disposed on the first conductive layer SD, that is, in a case where the first insulating layer BUF includes the first groove portion 41 that is concave in the direction proximate to the first substrate 110, and at least a portion of the first groove portion 41 is located between the first signal line DL and the first pattern LS, the undulating morphology of the first insulating layer BUF is proximate to an edge position of the first pattern LS. In this case, the second interval D2 is greater than or equal to 2 μm, that is, D2≥2 μm. In this way, it may not only greatly reduce the risk of signal interference between the gate portion 322 and the second electrode 22, but also reduce the risk of residue on the second electrode 22 at a position proximate to the edge of the first pattern LS, which is conducive to reducing the difficulty of development during the manufacturing process of the semiconductor layer ACT, and is conducive to improving the flatness of the second electrode 22 at the position proximate to the edge of the first pattern LS (referred to as a first region below), improving the electric field uniformity of the first region, and reducing the risk of light leakage in the liquid crystal layer in the first region.

For example, the second interval D2 may be in a range from 2 μm to 3 μm, or in a range from 3 μm to 4 μm, or in a range from 4 μm to 6 μm, etc. For example, the second interval D2 may be 2 μm, 2.5 μm, 3 μm, 3.5 μm, or 4 μm, etc., which will not be listed one by one in the embodiments of the present disclosure.

It can be understood that, as shown in FIG. 5, in a case where the first insulating layer BUF is directly disposed on the first conductive layer SD, the surface of the first insulating layer BUF away from the first substrate 110 has an undulating morphology at edges of the first pattern LS and the first signal line DL. The manufacturing process of the semiconductor layer ACT includes that a continuous and whole-layer initial semiconductor layer is formed on the surface of the first insulating layer BUF, the initial semiconductor layer also has an undulating morphology at the edges of the first pattern LS and the first signal line DL, and a distance between a portion of the initial semiconductor layer located above the first pattern LS and the first substrate 110 is greater than a distance between a portion of the initial semiconductor layer located in the pixel region and the first substrate 110. Then, a photoresist is coated on the initial semiconductor layer, and a thickness of a portion of the photoresist above the first pattern LS is less than a thickness of a portion of the photoresist within the pixel region 101. The photoresist layer is then patterned through exposure and development processes. During this process, the second interval D2 may prevent the formation of thick photoresist that is difficult to develop and remove at the edge of the first pattern LS, thereby avoiding the problem of residual first electrode 21 at the edge of the first pattern LS.

Referring to FIGS. 4 and 5, in a case where the first insulating layer BUF is directly disposed on the first conductive layer SD, that is, in a case where the first insulating layer BUF includes the first groove portion 41 that is concave in the direction proximate to the first substrate 110, and at least a portion of the first groove portion 41 is located between the first signal line DL and the first pattern LS, the undulating morphology of the first insulating layer BUF is further located at the edge position of the first signal line DL. In this case, the third interval D3 is greater than or equal to 4 μm, that is, D3≥4 μm. In this way, it may not only greatly reduce the risk of short circuit between the second electrode 22 and the first signal line DL, and reduce the magnitude of the parasitic capacitance generated between the second electrode 22 and the first signal line DL, but also reduce the risk of residue on the second electrode 22 at a position proximate to the edge of the first signal line DL, which is conducive to reducing the difficulty of development during the manufacturing process of the semiconductor layer ACT, and is conducive to improving the flatness of the second electrode 22 at the position proximate to the edge of the first signal line DL (referred to as the first region below), improving the electric field uniformity of the first region, and reducing the risk of light leakage in the liquid crystal layer in the first region.

For example, the third interval D3 may be in a range from 4 μm to 5 μm, or in a range from 5 μm to 7 μm, or in a range from 7 μm to 10 μm. For example, the third interval D3 may be 4 μm, 5 μm, 6.5 μm, 7 μm, or 8 μm, etc., which will not be listed one by one in the embodiments of the present disclosure.

In some embodiments, referring to FIGS. 8 and 9, in a case where the array substrate 100 further includes the planarization layer SOG, and the planarization layer SOG is located between the first conductive layer SD and the first insulating layer BUF, the surface of the planarization layer SOG away from the first substrate 110 is a flat surface, and orthogonal projections of the first conductive layer SD, the second interval D2, and the third interval D3 on the first substrate 110 are located within the range of the orthogonal projection of the planarization layer SOG on the first substrate 110. That is, the planarization layer SOG covers the first conductive layer SD, the second interval D2, and the third interval D3. In this case, portions of the first insulating layer BUF in the second interval D2 and the third interval D3 are located on the planarization layer SOG. Surfaces, away from the first substrate 110, of the portions of the first insulating layer BUF located in the second interval D2 and the third interval D3 and the portion of the first insulating layer BUF located above the first conductive layer (e.g., the first signal line DL and the first pattern LS) do not have the undulating morphology. Therefore, in the second interval D2 and the third interval D3, the semiconductor layer ACT does not have the problem of difficulty in developing thick photoresist. Based on this, the second interval D2 is greater than or equal to 1 μm, that is, D2≥1 μm. In a case where the second interval D2 is small, it may also ensure that there is no residual risk of the second electrode 22 at the position proximate to the edge of the first pattern LS, may reduce the magnitude of the parasitic capacitance generated between the second electrode 22 and the first pattern LS, and may greatly increase the area ratio of the second electrode 22, which is conducive to improving the pixel density of the array substrate.

For example, the second interval D2 may be in a range from 1 μm to 2 μm, or in a range from 2 μm to 4 μm, or in a range from 4 μm to 6 μm, etc. For example, the second interval D2 may be 1 μm, 2 μm, 3 μm, 3.5 μm, or 5 μm, which will not be listed one by one in the embodiments of the present disclosure.

In some embodiments, in a case where the array substrate 100 further includes the planarization layer SOG, and the planarization layer SOG is located between the first conductive layer SD and the first insulating layer BUF, referring to FIGS. 8 and 9, the third interval D3 is greater than or equal to 3 μm, that is, D3≥3 μm. In this way, the risk of short circuit between the second electrode 22 and the first signal line DL may be reduced, and the magnitude of the parasitic capacitance generated between the second electrode 22 and the first signal line DL may be reduced, which is conducive to increasing the region ratio of the second electrode 22 and the pixel density of the array substrate.

For example, the third interval D3 may be in a range from 3 μm to 4 μm, or in a range from 4 μm to 6 μm, or in a range from 6 μm to 10 μm, etc. For example, the third interval D3 may be 3 μm, 5 μm, 6 μm, 7.5 μm, or 9 μm, etc., which will not be listed one by one in the embodiments of the present disclosure.

In some embodiments, as shown in FIG. 5, in a case where the first insulating layer BUF is directly disposed on the first conductive layer SD, the surface of the first insulating layer BUF changes with the change of the undulating morphology of the surface on which the first insulating layer BUF is located. The first insulating layer BUF includes the first groove portion 41 that is concave in the direction proximate to the first substrate 110. At least a portion of the first groove portion 41 is located between the first signal line DL and the first pattern LS, or, at least a portion of the orthogonal projection of the first groove portion 41 on the first substrate 110 is located between the orthogonal projections of the first signal line DL and the first pattern LS on the first substrate 110.

The first groove 41 includes two first side walls 42 disposed opposite to each other. In a cross section (e.g., the cross section shown in FIG. 5) perpendicular to the first substrate 110 and parallel to the arrangement direction (i.e., the first direction X) of the first signal line DL and the first pattern LS, the first side wall 42 has an acute included angle with the first substrate 110, or, the first side wall 42 is an inclined side wall.

Continuing to refer to FIG. 5, the first portion 11 of the semiconductor pattern 10 includes two first sub-portions 14 covering the two first side walls 42, and a second sub-portion 15 covering other regions of the first insulating layer BUF. A thickness of the first sub-portion 14 is less than that of the second sub-portion 15. In general, the semiconductor layer ACT is formed by a thin film deposition process. Since the first side wall 42 is an inclined side wall, the thickness of the material of the semiconductor layer ACT deposited on the first side wall 42 is small. The thickness of the first sub-portion 14 and the second sub-portion 15 refers to dimensions in a direction perpendicular to the surface on which they are located. For example, the thickness of the first sub-portion 14 refers to a dimension of the first sub-portion 14 along a direction perpendicular to the first side wall 42, and the thickness of the second sub-portion 15 refers to a dimension of the second sub-portion 15 along the third direction Z.

In some embodiments, in a cross section (e.g., the cross section shown in FIG. 5) perpendicular to the first substrate 110 and perpendicular to an extending direction of the edge of the first conductive layer SD, the side wall 16 of the first conductive layer SD and the first substrate 110 have a first included angle α therebetween, and the first included angle α is less than or equal to 50°. In this way, it is conducive to reducing the inclination degree of the first side wall 42, and further conducive to depositing the semiconductor layer ACT on the first side wall 42, which may reduce the risk of the semiconductor layer ACT breaking on the first side wall 42 (for example, the deposition is discontinuous or the thickness of the film does not satisfy the requirements). Or, it is conducive to increasing the thickness of the first sub-segment 14 on the first side wall 42 and reducing the thickness of the portion of the semiconductor layer ACT located on a plane (e.g., the thickness of the channel structure 13 and the second electrode 22), which is conducive to reducing the manufacturing cost of the semiconductor layer ACT and improving the transmittance of the second electrode 22.

For example, the first included angle α may be in a range from 40 ° to 50°, or the first included angle α may be in a range from 30° to 40°. For example, the first included angle α may be 30°, 35°, 40°, 45°, 47° or 50°, etc., which will not be listed one by one in the embodiments of the present disclosure.

In some embodiments, a ratio K of the thickness of the first sub-portion 14 to the thickness of the second sub-portion 15 is greater than or equal to 40%, that is, a thickness retention rate of a climbing portion of the semiconductor layer ACT at the first side wall 42 is greater than or equal to 40%. For example, the ratio K is in a range from 40% to 50%, or in a range from 50% to 60%, or in a range from 60% to 80%. For example, the ratio K of the thickness of the first sub-portion 14 to the thickness of the second sub-portion 15 may be 40%, 45%, 50%, 60% or 70%, etc., which will not be listed one by one in the embodiments of the present disclosure. The ratio K of the thickness of the first sub-segment 14 to the thickness of the second sub-segment 15 is negatively correlated with the first included angle α, that is, the greater the value of the first included angle α, the less the ratio K of the thickness of the first sub-segment 14 to the thickness of the second sub-segment 15.

In some embodiments, the thickness of the first sub-portion 14 is greater than or equal to 150 Å, which may reduce the risk of short circuit in the first sub-portion 14 and ensure that the resistance of the first sub-portion 14 satisfies the use requirements. For example, the thickness of the first sub-portion 14 is in a range from 150 Å to 200 Å, or in a range from 200 Å to 300 Å, or in a range from 300 Å to 500 Å. For example, the thickness of the first sub-portion 14 may be 150 Å, 180 Å, 200 Å, 250 Å, or 300 Å, etc., which will not be listed one by one in the embodiments of the present disclosure.

In some embodiments, referring to FIGS. 8 and 9, in a case where the array substrate 100 further includes the planarization layer SOG, the planarization layer SOG is located between the first conductive layer SD and the first insulating layer BUF, and the semiconductor layer ACT includes the second electrode 22 layer, the planarization layer SOG may only cover the region of the first conductive layer SD. In this way, the influence of the planarization layer SOG on the transmittance of the pixel region 101 may be greatly reduced, which is conducive to improving the light transmittance of the array substrate.

Referring to FIG. 9, the first insulating layer BUF will form the undulating morphology at the edge of the planarization layer SOG. For example, the first insulating layer BUF will form a second side wall 43 at the edge of the planarization layer SOG. In a cross section (e.g., the cross section shown in FIG. 9) perpendicular to the first substrate 110 and perpendicular to an extending direction of the side wall of the planarization layer SOG, the second side wall 43 has an acute included angle with the first substrate 110, that is, the second side wall 43 is an inclined side wall.

In some embodiments, in the cross section (e.g., the cross section shown in FIG. 9) perpendicular to the first substrate 110 and perpendicular to the extending direction of the side wall of the planarization layer SOG, there is a second included angle β between the side wall of the planarization layer SOG and the first substrate 110, and the second included angle β is less than or equal to 50°. In this way, it is conducive to reducing the inclination degree of the second side wall 43, and is conducive to depositing the semiconductor layer ACT on the second side wall 43, which may reduce the risk of the semiconductor layer ACT breaking on the second side wall 43 (for example, the deposition is discontinuous or the thickness of the film does not satisfy the requirements). It is further conducive to reducing the thickness of portions of the semiconductor layer ACT located on a plane (e.g., the thickness of the channel structure 13 and the second electrode 22), which is conducive to reducing the manufacturing cost of the semiconductor layer ACT and improving the transmittance of the second electrode 22.

For example, the second included angle β may be in a range from 40°to 50°, or in a range from 30°to 40°. For example, the second included angle β may be 30°, 35°, 40°, 45°, 47°or 50°, etc., which will not be listed one by one in the embodiments of the present disclosure.

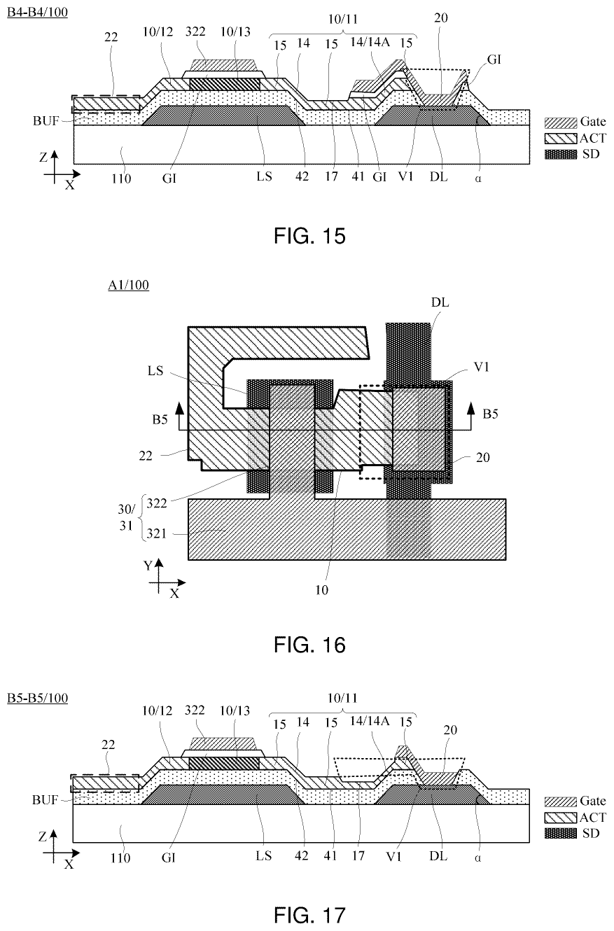

In some embodiments, taking the array substrate 100 not including the planarization layer SOG as an example, referring to FIGS. 11 and 12, the manufacturing process of the array substrate 100 includes that the first conductive layer SD, the first insulating layer BUF, the semiconductor layer ACT and the second insulating layer GI are formed on the first substrate 110 in sequence, and then the first via hole V1 is formed. A portion of the first via hole V1 penetrates the second insulating layer GI and the first insulating layer BUF, and exposes a portion of the first signal line DL. Another portion of the first via hole V1 passes through the second insulating layer GI, and exposes a portion of the first portion 11 (as shown in FIG. 11). Then, a continuous and whole-layer initial gate line layer is formed, and the initial gate line layer covers the first via hole V1. The initial gate line layer is then patterned to form the connecting electrode 20 and the signal line group 30 (as shown in FIG. 12). A whole of the connecting electrode 20 may be located in the first via hole V1 (as shown in FIG. 12), or a portion of the connecting electrode 20 located in the first via hole V1 and another portion of the connecting electrode 20 covers the surface of the second insulating layer GI (as shown in FIG. 15).

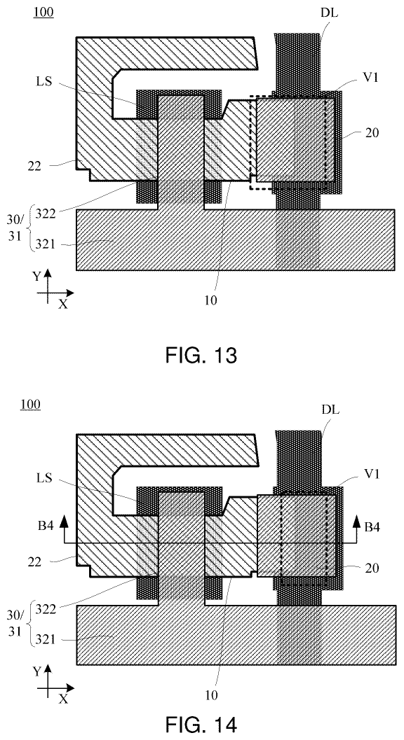

In some embodiments, as shown in FIGS. 12 and 13, a first sub-portion 14 of the two first sub-portions 14 proximate to the first signal line DL is a target sub-portion 14 Å. The first via hole V1 penetrates the second insulating layer GI and exposes the target sub-portion 14 Å, and the connecting electrode 20 covers the target sub-portion 14 Å. In this case, in the process of forming the first via hole V1, a portion of the first sub-portion 14 may be etched and removed, thereby causing the thickness of the first sub-portion 14 to be reduced. A dimension of the channel structure 13 in a direction perpendicular to the first substrate 110 (e.g., the third direction Z) is greater than or equal to 300 Å. In this way, it may be ensured that the target sub-portion 14 Å will not be broken even if a portion of the target sub-portion 14A is removed during the process of forming the first via hole V1, which is conducive to improving the continuity and conductivity of the target sub-portion 14 Å. In addition, the first via hole V1 occupies a small area, which is conducive to improving the pixel density of the array substrate 100.

For example, the dimension of the channel structure 13 in the third direction Z may be in a range from 300 Å to 400 Å, or in a range from 400 Å to 500 Å, or in a range from 500 Å to 600 Å. In this way, the thickness of the channel structure 13 may be reduced as much as possible while ensuring the continuity of the first sub-portion 14, and reducing the consumption of the semiconductor layer ACT and the thickness of the second electrode 22, which is conducive to improving the transmittance of the second electrode 22. For example, the dimension of the channel structure 13 in the third direction Z may be 300 Å, 350 Å, 400 Å, 450 Å or 550 Å, etc., which will not be listed one by one in the embodiments of the present disclosure.

It will be noted that, in the semiconductor layer ACT, the thickness of the channel structure 13 is a thickness of the deposited semiconductor material during the manufacturing process of the semiconductor layer ACT. During the process of patterning the second insulating layer GI, the first portion 11, the second portion 12 and the second electrode 22 may be partially removed. Therefore, in some embodiments, the thickness of the first portion 11, the second portion 12 and the second electrode 22 are all less than or equal to the thickness of the channel structure 13.

In some other embodiments, referring to FIGS. 14 and 15, the first sub-portion 14 of the two first sub-portions 14 proximate to the first signal line DL is the target sub-portion 14 Å. The first via hole V1 penetrates the second insulating layer GI, and there is an interval between the first via hole V1 and the target sub-portion 14 Å. In this case, in the process of forming the first via hole V1, the target sub-portion 14 Å will not be etched, which is conducive to maintaining the thickness of the target sub-portion 14 Å. The dimension of the channel structure 13 in the direction perpendicular to the first substrate 110 (e.g., the third direction Z) is greater than or equal to 100 Å. In this way, the thickness of the semiconductor layer ACT may be reduced, the consumables of the semiconductor layer ACT may be reduced, and the thickness of the second electrode 22 may be reduced, while ensuring the continuity and conductivity of the target sub-portion 14 Å, which is conducive to improving the transmittance of the second electrode 22.

It will be noted that after forming the connecting electrode 20, the manufacturing method of the array substrate further includes patterning the second insulating layer GI. During the process of patterning the second insulating layer GI, a portion of the second insulating layer above the first sub-portion 14 may also be etched and removed. During this process, the first sub-portion 14 may be partially etched and removed simultaneously. During this process, an etching degree of the first sub-portion 14 is small, a thickness reduction (e.g., in a range from 20 Å to 70 Å) of the first sub-portion 14 is small, and the dimension of the channel structure 13 in the direction perpendicular to the first substrate 110 (e.g., the third direction Z) is greater than or equal to 100 Å.

For example, the dimension of the channel structure 13 in the third direction Z may be in a range from 100 Å to 200 Å, or in a range from 200 Å to 300 Å, or in a range from 300 Å to 500 Å. In this way, the thickness of the channel structure 13 may be reduced as much as possible while ensuring the continuity of the first sub-portion 14, and reducing the consumption of the semiconductor layer ACT and the thickness of the second electrode 22, which is conducive to improving the transmittance of the second electrode 22. For example, the dimension of the channel structure 13 in the third direction Z may be 100 Å, 150 Å, 200 Å, 250 Å or 400 Å, etc., which will not be listed one by one in the embodiments of the present disclosure.

In some embodiments, referring to FIG. 16 and FIG. 17, the first sub-portion 14 of the two first sub-portions 14 proximate to the first signal line DL is the target sub-portion 14 Å. The first via hole V1 penetrates the second insulating layer GI and exposes the target sub-portion 14 Å, and there is an interval between the connecting electrode 20 and the target sub-portion 14 Å. In this case, during the process of forming the first via hole V1 and the subsequent process of patterning the second insulating layer GI, the target sub-portion 14 Å may be partially etched and removed. The dimension of the channel structure 13 in the direction perpendicular to the first substrate is greater than or equal to 600 Å, so that the risk of the target sub-portion 14 Å being etched through and broken may be greatly reduced.

For example, the dimension of the channel structure 13 in the third direction Z may be in a range from 600 Å to 700 Å, or in a range from 700 Å to 900 Å, or in a range from 900 Å to 1200 Å. For example, the dimension of the channel structure 13 in the third direction Z may be 600 Å, 750 Å, 850 Å, 900 Å or 1000 Å, etc., which will not be listed one by one in the embodiments of the present disclosure.

In some embodiments, after forming the connecting electrode 20, the second insulating layer GI may be patterned. As shown in FIGS. 5, 9, 12, 15 and 17, in this case, the second insulating layer GI substantially does not extend on the entire array substrate 100, and the position of the second insulating layer GI is substantially coincided with the position of the signal line group 30.

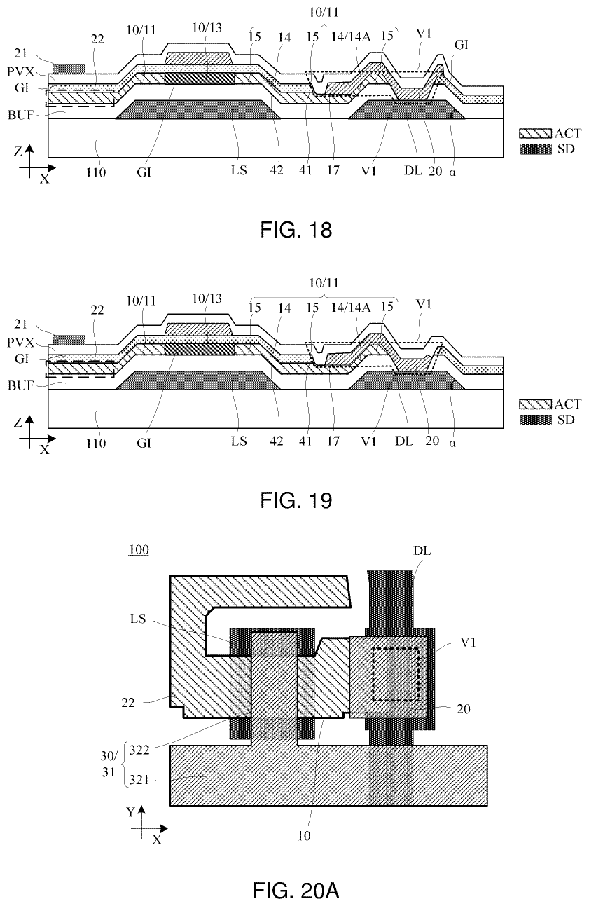

In some other embodiments, after the connecting electrode 20 is formed, the second insulating layer GI may not be patterned. Referring to FIG. 18, in this case, the second insulating layer GI substantially extends on the entire array substrate 100.

In some embodiments, referring to FIG. 9, in a case where the second insulating layer GI substantially does not extend on the entire array substrate 100, the connecting electrode 20 may be completely located within the range of the first via hole V1. In this case, a side of the connecting electrode 20 proximate to the first substrate 110 does not include the second insulating layer GI.

In some embodiments, referring to FIGS. 12 and 15, in a case where the second insulating layer GI substantially does not extend on the entire array substrate 100, the connecting electrode 20 may be partially located within the range of the first via hole V1 and partially located outside the range of the first via hole V1. In this case, the connecting electrode 20 and the first insulating layer BUF include at least a portion of the second insulating layer GI therebetween (as shown in FIG. 12), and/or the connecting electrode 20 and the first portion 11 include at least a portion of the second insulating layer GI therebetween (as shown in FIG. 15).

In some embodiments, referring to FIG. 15, the connecting electrode 20 may expose at least a portion of the first portion 11, for example, expose a portion of the first portion 11 located on a side of the connecting electrode 20 proximate to the channel structure 13. In this case, a surface of the first portion 11 away from the first substrate 110 includes a second groove portion 17 that is concave toward a side proximate to the first substrate 110. The second groove portion 17 may be formed in the process of forming the connecting electrode 20 and patterning the second insulating layer GI.

In some embodiments, in a case where the second insulating layer GI extends substantially on the entire array substrate 100, referring to FIG. 19, the connecting electrode 20 may be completely located within the range of the first via hole V1. In this case, the side of the connecting electrode 20 proximate to the first substrate 110 does not include the second insulating layer GI. Or, referring to FIG. 18, the connecting electrode 20 may be partially located within the first via hole V1 and partially located outside the first via hole V1. In this case, at least a portion of the connecting electrode 20 is located on a surface of the second insulating layer GI away from the first substrate 110.

It can be understood that the relative positional relationship among the connecting electrode 20, the first via hole V1, the first portion 11 and the first signal line DL is not limited to the above embodiments, as long as the same technical concept is adopted.

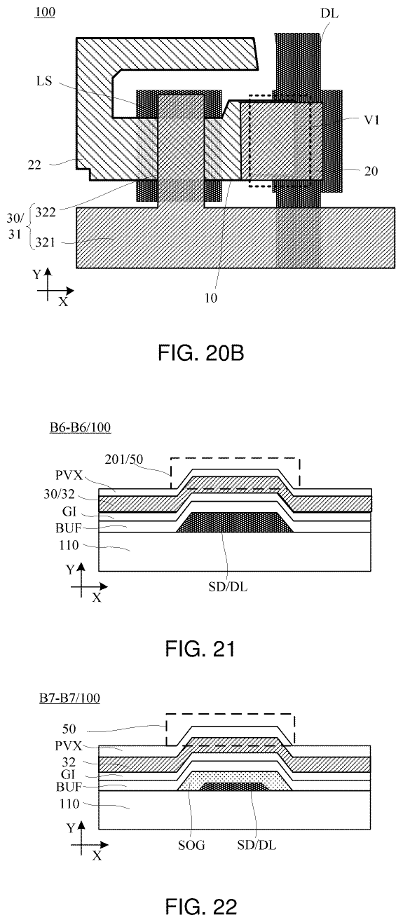

For example, referring to FIG. 20A, the orthogonal projections of the first portion 11 and the first signal line DL on the first substrate 110 partially overlap. An orthogonal projection of the first via hole V1 on the substrate 110 is located within the range of the orthogonal projection of the first signal line DL on the first substrate 110. The connecting electrode 20 completely covers the first via hole V1, and the edge of the connecting electrode 20 extends out of the edge of the first via hole V1. For example, referring to FIG. 20B, the orthogonal projections of the first portion 11 and the first signal line DL on the first substrate 110 partially overlap. The orthogonal projection of the first via hole V1 on the substrate 110 is partially located within the range of the first signal line DL, and partially located between the first signal line DL and the first pattern LS. The connecting electrode 20 covers the edges of the first via hole V1 along the first direction X, and both ends of the connecting electrode 20 in the second direction Y are located within the range of the first via hole V1. Of course, the embodiments of the present disclosure are not limited thereto, and any other feasible implementations may be considered, which will not be exemplified one by one in the embodiments of the present disclosure.

In some embodiments, referring to FIGS. 21 and 22, a region (referred to as a main spacer region below) 201 where the orthogonal projections of the signal line group 30 and the first signal line DL on the first substrate 110 are overlapped protrudes toward a side away from the first substrate 110 to form a columnar structure 50. That is, a surface, in the main spacer region 201, of the array substrate 100 away from the first substrate 110 protrudes in a direction away from the first substrate 110 (i.e., in a direction from bottom to top in FIGS. 21 and 22) to form the columnar structure 50. The columnar structure 50 is configured to support the spacer on the color filter substrate.

In some embodiments, referring to FIG. 21, in a case where the first insulating layer BUF is directly disposed on the first conductive layer SD, a dimension of the first conductive layer SD along the direction perpendicular to the first substrate 110 (e.g., the third direction Z) is in a range from 0.4 μm to 0.8 μm. In this way, it is conducive to increasing a height difference (i.e., a step difference) between the first signal line DL and the first substrate 110, and further conducive to forming the columnar structure 50 in the main spacer region 201 of the array substrate 100 and on the surface of the array substrate 100 away from the first substrate 110. For example, the dimension of the first conductive layer SD is 0.4 μm, 0.5 μm, 0.65 μm, 0.7 μm, or 0.8 μm, which will not be listed one by one in the embodiments of the present disclosure.

In some embodiments, referring to FIG. 22, in a case where the array substrate 100 further includes a planarization layer SOG, the planarization layer SOG is located between the first conductive layer SD and the first insulating layer BUF, and the planarization layer SOG at least covers the first signal line DL, the first pattern LS, and the interval (i.e., the second interval D2) between the first signal line DL and the first pattern LS, at least a portion of the orthogonal projection of the second electrode 22 on the first substrate 110 does not overlap with at least a portion of the orthogonal projection of the planarization layer SOG on the first substrate 110. In this way, it may reduce the area of the planarization layer SOG in the pixel region 101, thereby improving the transmittance of the pixel region 101. It may also be conducive to forming a height difference between the edge of the planarization layer SOG and the first substrate 110, thereby facilitating the formation of the columnar structure 50 in the main spacer region 201 of the array substrate 100 and on the surface away from the first substrate 110. For example, the dimension of the first conductive layer SD is 0.4 μm, 0.55 μm, 0.6 μm, 0.7 μm, or 0.8 μm, which will not be listed one by one in the embodiments of the present disclosure.

As shown in FIG. 22, in a case where the array substrate 100 further includes the planarization layer SOG, the thickness of the first conductive layer SD may not be limited, which is conducive to reducing the thickness of the first conductive layer SD and reducing the width of the first signal line DL, thereby improving the aperture ratio of the array substrate 100 and the transmittance of the array substrate 100.

In some embodiments, the array substrate 100 further includes an alignment film (not shown in the figure) disposed on a side of the first electrode 21 away from the first substrate 110. The alignment film is used to limit an initial deflection angle of the liquid crystal molecules in the liquid crystal layer, so that the liquid crystal molecules in the liquid crystal layer may be arranged at a certain angle without an action of an electric field.

In the following embodiments, some embodiments of the present disclosure will be exemplarily described by taking a case where the first insulating layer BUF is directly disposed on the first conductive layer SD (the array substrate 100 does not include the planarization layer SOG), but the embodiments of the present disclosure are not limited thereto.

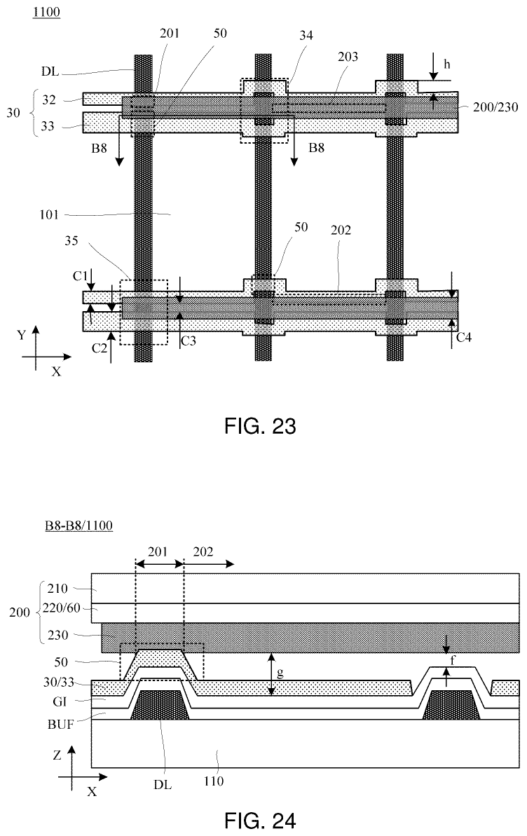

In some embodiments, as shown in FIGS. 23 to 26, the array substrate 100 includes a plurality of first signal lines DL arranged at intervals along the first direction X, and a plurality of signal line groups 30 arranged at intervals along the second direction Y. The plurality of first signal lines DL are extended along the second direction Y, and the plurality of signal line groups 30 are extended along the first direction X. The plurality of first signal lines DL and the plurality of signal line groups 30 intersect each other to form a grid structure.

The color filter substrate 200 includes a plurality of spacers 230. The spacer 230 is in a strip shape. For example, the plurality of strip-shaped spacers 230 are disposed on a side of the color filter substrate 200 proximate to the array substrate 100 and extend along the first direction X. An orthogonal projection of the spacer 230 on the array substrate 100 partially overlaps with the orthogonal projections of the signal line group 30 and the first signal line DL on the array substrate 100.

The present application utilizes the thickness of the signal line group 30 and the first signal line DL in cooperation with the strip-shaped spacer 230 to form a structure for supporting the liquid crystal layer (a thickness of a liquid crystal cell). In a case where the spacer 230 is displaced, the spacer 230 may be supported by the first signal line DL and the signal line group 30, so as to prevent the spacer 230 from scratching a portion of the alignment film located in the pixel region 101.

Referring to FIG. 24, the color filter substrate 200 further includes a second substrate 210 and a filter layer 220. The second substrate 210 may be a rigid substrate. The rigid substrate may be, for example, a glass substrate or a polymethyl methacrylate (PMMA) substrate. The second substrate 210 may also be a flexible substrate. For example, the flexible substrate may be a polyethylene terephthalate (PET) substrate, a polyimide (PI) substrate, or a polyethylene naphthalate (PEN) substrate. It can be understood that the second substrate 210 may be of various types of substrates, which may be selected and set according to actual needs, and will not be limited in the embodiments of the present disclosure.

A side of the second substrate 210 proximate to the array substrate 100 is provided with the filter layer 220. The filter layer 220 includes a black matrix 60 and a filter portion (not shown in the figure). The filter portion is disposed corresponding to the pixel region 101. An orthogonal projection of the filter portion on the array substrate 100 covers the pixel region 101. The filter portion includes a red filter portion, a green filter portion and a blue filter portion. Different pixel regions 101 correspond to different filter portions, respectively.

An orthogonal projection of the black matrix 60 on the array substrate 100 covers regions other than the pixel regions 101. For example, the orthogonal projection of the black matrix 60 on the array substrate 100 covers the first signal lines DL, the signal line groups 30, the first patterns LS, etc., and the black matrix 60 further covers the spacer structures on the color filter substrate 200. The black matrix 60 is further configured to separate different pixel regions 101, so as to reduce the risk of cross-color between different pixel regions, thereby affecting the final display effect. The black matrix 60 may also prevent the spacers 230 from slipping and causing abnormal panel display. A side of the color filter substrate 200 proximate to the array substrate 100 is provided with an alignment film (not shown in the figure).

The liquid crystal layer 300 between the array substrate 100 and the color filter substrate 200 is supported by the spacers 230. An end of the spacer 230 proximate to the array substrate (i.e., a lower end surface) is supported on the array substrate 100, and an end of the spacer 230 proximate to the color filter substrate 200 (i.e., an upper end surface) is supported on the color filter substrate 200, so as to maintain a certain thickness of the liquid crystal layer 300. For example, the spacer 230 may be manufactured on the color filter substrate 200.

In some embodiments, referring to FIGS. 23 to 27, the signal line group 30 includes one or more second signal line 32 and one or more third signal line 33. The structure and function of the second signal line 32 are mentioned above, which will not be repeated here. The third signal line 33 is configured to be connected to the first electrode. The third signal line 33 is further configured to provide a stable voltage for terminals of a liquid crystal capacitor Clc and a storage capacitor Cst, so that the liquid crystal capacitor Clc and the storage capacitor Cst may maintain a stable voltage difference, thereby maintaining a directional deflection angle of the liquid crystal molecules.

For example, a signal line group 30 includes a second signal line 32 and a third signal line 33. The second signal line 32 may control the turn-on and turn-off between first signal lines DL of a row of pixel regions 101 and second electrodes of the row of pixel regions 101 through a row of thin film transistors. The third signal line 33 provides a stable voltage for terminals of liquid crystal capacitors Clc and storage capacitors Cst of an adjacent row of pixel regions 101.

In some embodiments, referring to FIG. 23, the orthogonal projection of the spacer 230 on the array substrate 100 covers a region between the second signal line 32 and the third signal line 33 in the signal line group 30. Furthermore, the orthogonal projection of the spacer 230 on the array substrate 100 partially overlaps with the second signal line 32, and the orthogonal projection of the spacer 230 on the array substrate 100 partially overlaps with the third signal line 33. That is, within a length range of the spacer 230, the orthogonal projection of the spacer 230 on the array substrate 100 covers a portion of the second signal line 32, a portion of the third signal line 33, and the region between the second signal line 32 and the third signal line 33.

In some embodiments, referring to FIG. 23, a dimension of the second signal line 32 in the second direction Y is C1, a dimension of the third signal line 33 in the second direction Y is C2, an interval between the second signal line 32 and the third signal line 33 is C3, and a dimension of an end of the spacer 230 proximate to the array substrate 100 in the second direction Y is C4. In a case where the dimension C2 of the third signal line 33 in the second direction Y is greater than the dimension C1 of the second signal line 32 in the second direction Y (i.e., C2>C1), C4 is equal to a sum of C3 and C1 (i.e., C4=C3+C1). Alternatively, in a case where the dimension C1 of the second signal line 32 in the second direction Y is greater than the dimension C2 of the third signal line 33 in the second direction Y (i.e., C1>C2), C4 is equal to a sum of C3 and C2 (i.e., C4=C3+C2). That is, the dimension C4 of the end of the spacer 230 proximate to the array substrate 100 in the second direction Y is equal to a sum of the interval C3 between the second signal line 32 and the third signal line 33 and a dimension of a smaller one of the dimensions of second signal line 32 and the third signal line 33 in the second direction Y. In this way, even if there is a certain alignment deviation between the spacer 230 and the array substrate 100, in a case where the spacer at least partially covers the region between the second signal line 32 and the third signal line 33, a total contact area between the spacer 230 and the second signal line 32, and between the spacer 230 and the third signal line 33 remains unchanged. In this way, it may be ensured that the spacer 230 provides stable support for the liquid crystal layer 300, thereby ensuring that the liquid crystal layer 300 may maintain a stable thickness, thereby ensuring the display effect of the display substrate.

In some embodiments, a side of the spacer 230 away from the color filter substrate 200 is at an equal distance from the color filter substrate 200 (the second substrate 210). The length of the spacer 230 is greater than a distance between two adjacent first signal lines DL. The overlapping regions of the first signal lines DL and the signal line groups 30 forms a plurality of columnar structures 50 protruding toward the color filter substrate 200, and the side of the spacer 230 away from the color filter substrate 200 abuts against a part of the columnar structures 50. In this way, the spacers 230 are cooperated with the first signal lines DL and the signal line groups 30 to form different spacer regions.

A portion of the side of the spacer 230 away from the color filter substrate 200 that is abuts against the part of the columnar structures 50 forms the main spacer region 201. A portion of the orthogonal projection of the spacer 230 on the array substrate 100 that overlaps with the first signal lines DL or the signal line groups 30 but not overlaps with the columnar structure 50 forms a first secondary spacer region 202. A portion of the orthogonal projection of the spacer 230 on the array substrate 100 that overlaps with the region between the second signal line 32 and the third signal line 33 in the signal line group 30 forms a second secondary spacer region 203.

A side of the columnar structure 50 proximate to the color filter substrate 200 abuts against the spacer 230. A distance between a side of a region of the first signal line DL or the signal line group 30 other than the columnar structure 50 proximate to the color filter substrate 200 and the spacer 230 is f. A distance between the region between the second signal line 32 and the third signal line 33 in the signal line group 30 and the spacer 230 is g. g is greater than f, and f is greater than 0 (i.e., g>f>0). In this way, the spacer 230 is cooperated with the first signal line DL and the signal line group 30 to form the main spacer region 201, the first secondary spacer region 202 and the second secondary spacer region 203 with step differences.

In a case where the display substrate is in a normal state, the main spacer region 201 of the spacer 230 provides support for the thickness of liquid crystal cell. In a case where the display substrate 1100 is pressed, the color filter substrate 200 is squeezed toward the array substrate 100, and the spacer 230 is squeezed and deformed. In this case, the first secondary spacer region 202 participates in supporting the thickness of the liquid crystal cell, that is, the spacer 230 is in contact with an upper surface of the array substrate 100 (a surface proximate to the color filter substrate) where the second signal line 32 and the third signal line 33 are located. In a case where the display substrate is pressed strongly, the degree of squeezing of the color filter substrate 200 against the array substrate 100 is increased, and the degree of deformation of the spacer 230 is increased. In this case, the second secondary spacer region 203 also participates in supporting the thickness of the liquid crystal cell. That is, the spacer 230 is further in contact with the upper surface of the array substrate in the region between the second signal line 32 and the third signal line 33.

In some embodiments, the signal line group 30 is provided with a plurality of wiring regions 34 along the length direction (i.e., the first direction X) thereof. A position where at least one signal line group 30 intersects the first signal line DL is provided with the wiring region 34. A position where at least one of the one or more second signal line 32 and/or at least one of the one or more third signal line 33 intersects the first signal line DL is provided with the wiring region 34. In the wiring region 34, the orthogonal projection of the spacer 230 on the array substrate 100 has no overlapping region with the columnar structure 50.

For example, the signal line group 30 includes a second signal line 32 and a third signal line 33. The second signal line 32 and the third signal line 33 extend along the length direction (i.e., the first direction X) of the signal line group 30 in the non-wiring region 35. In the wiring region 34, the second signal line 32 is bent for a distance in a direction away from the third signal line 33, and then extends along the length direction of the signal line group 30. After bypassing the first signal line DL, the second signal line 32 is bent and extended in a direction proximate to the third signal line 33 to a position colinear with a second signal line 32 in the non-wiring region 35, and then continues to extend along the length direction of the signal line group 30. That is, in the wiring region 34, the second signal line 32 protrudes along the second direction Y to avoid the spacer 230. In the wiring region 34, the third signal line 33 is bent for a distance away from the second signal line 32, and then extends along the length direction of the signal line group 30. After bypassing the columnar structure 50, the third signal line 33 is bent and extended in a direction proximate to the second signal line 32 to a position colinear with a third signal line 33 in the non-wiring region 35, and then continues to extend along the length direction of the signal line group 30. That is, in the wiring region 34, the third signal line 33 protrudes along the second direction Y to avoid the spacer 230. In this way, an original main spacer region 201 in the wiring region 34 is changed into a first secondary spacer region 202.

For example, in the wiring region 34, the distance that the second signal line 32 is bent away from the third signal line 33 is h. A maximum alignment deviation between the array substrate 100 and the color filter substrate 200 in the second direction Y is e. h is greater than or equal to e. The structure formed in the wiring region 34 where the second signal line 32 and the third signal line 33 sandwich the spacer 230 may effectively prevent the spacer 230 from being displaced in the second direction Y.

In some embodiments, on average, a spacer 230 is provided for every twenty-four pixel regions 101 in the display substrate. For example, in twenty-four pixel regions 101 arranged in two rows and twelve columns, a spacer 230 at least crosses over thirteen first signal lines DL in the length direction thereof, that is, the spacer 230 crosses over twelve pixel regions 101 in the length direction thereof. The orthogonal projection of the spacer 230 on the array substrate 100 has an overlapping region with the thirteen first signal lines DL and has an overlapping region with a signal line group 30. At least eleven of the intersection positions between the thirteen first signal lines DL and the signal line group 30 are provided with wiring regions 34. In this way, a contact density ratio between the main spacer region 201 and the first secondary spacer region 202 is close to 1:100. The main spacer region 201 and the first secondary spacer region 202 with this contact density ratio may satisfy the requirements of supporting the thickness of the liquid crystal cell and having no dark spots under external pressure.

Of course, the above-mentioned arrangement of the spacer 230 and the wiring region 34 may be determined according to actual needs. For example, a spacer 230 may be provided for every 23, 24, 25, 26 or 27 pixel regions 101 on average. A spacer 230 crosses over 12, 13, 14, 15 or 16 first signal lines DL in the length direction thereof, that is, the spacer 230 crosses over 11, 12, 13, 14 or 15 pixel regions 101 in the length direction thereof. The number of wiring regions 34 may also be 11, 12, 13, 14, or 15. It only needs to satisfy that the contact density of the main spacer region 201 is close to 200 μm²/mm² and the contact density of the first secondary spacer region 202 is close to 20000 μm²/mm².

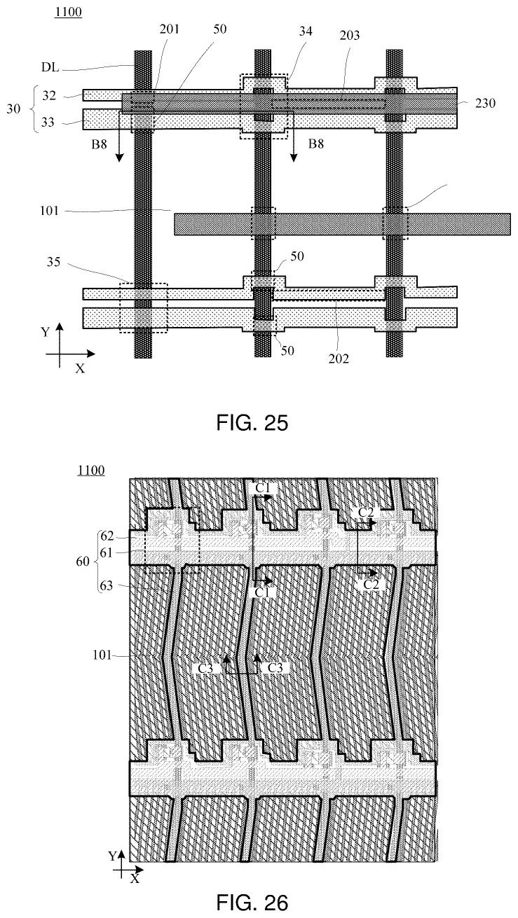

The spacer 230 crosses over a plurality of first signal lines DL in the length direction thereof. As shown in FIG. 25, in a case where the spacer 230 is displaced greatly in the second direction Y, for example, in a case where the spacer 230 is displaced in the second direction Y to be not overlapped with the signal line group 30, the first signal line DL may still support the spacer 230. That is, in a case where the spacer 230 is displaced greatly in the second direction Y, the first secondary spacer region 202 formed by the overlap of the main spacer region 201 and the signal line group 30 will be lost, but the first secondary spacer region 202 formed by the overlap of the main spacer region 201 and the first signal line DL will not be lost. Therefore, in a case where the spacer 230 is displaced greatly in the second direction Y, the spacer 230 will not scratch the alignment film on the array substrate 100.

For example, the spacers 230 may be disposed according to requirements. For example, a main spacer region 201 and six to twelve first secondary spacer regions 202 may be disposed in twenty-four pixel regions 101 arranged in three rows and eight columns. Alternatively, a main spacer region 201 and six to twelve first secondary spacer regions 202 may be disposed in twenty-four pixel regions 101 arranged in four rows and six columns, or the like. It only needs to satisfy that the spacers 230 are evenly arranged on the entire surface and the contact density ratio between the main spacer region 201 and the first secondary spacer region 202 is close to 1:100.

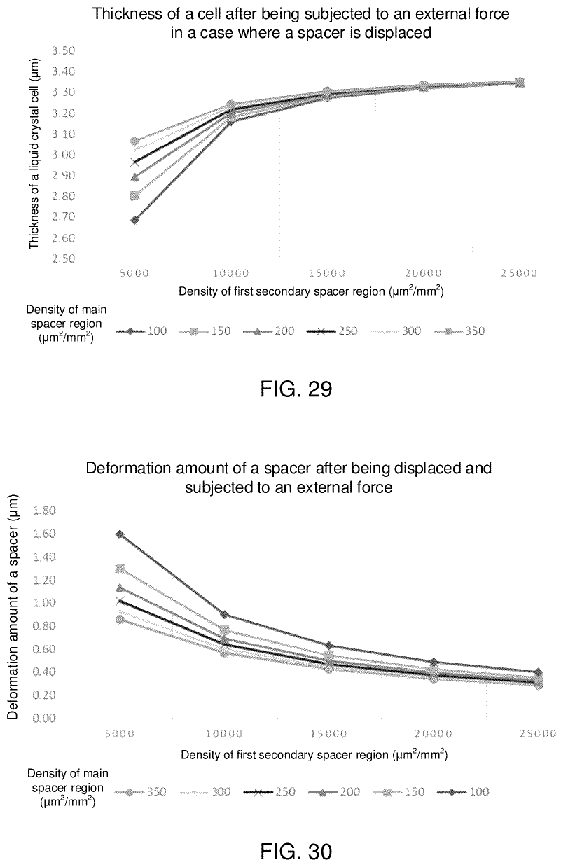

FIGS. 28 and 29 show the thickness of the liquid crystal cell of the display substrates, subjected to external force, having the main spacer regions 201 and the first secondary spacer regions 202 which have different contact densities when the spacer 230 is not displaced and when spacer 230 is displaced.

In FIGS. 28 and 29, a horizontal axis represents the contact density (μm²/mm²) of the first secondary spacer region 202, and a vertical axis represents the thickness of the liquid crystal cell (μm). Six lines from top to bottom in FIG. 28 represent the contact density of the main spacer region 201 as 100 μm²/mm², 150 μm²/mm², 200 μm²/mm², 250 μm²/mm², 300 μm²/mm², and 350 μm²/mm², respectively. Six lines from top to bottom in FIG. 29 represent the contact densities of the main spacer region 201 as 350 μm²/mm², 300 μm²/mm², 250 μm²/mm², 200 μm²/mm², 150 μm²/mm², and 100 μm²/mm², respectively. It is obvious that as the contact density of the first secondary spacer region 202 is increased, the thickness of the liquid crystal cell after the display substrate is subjected to external force is gradually increased. In a case where the contact density of the main spacer region 201 is 200 μm²/mm² and the contact density of the first secondary spacer region 202 is 20000 μm²/mm², the spacer 230 may provide a good supporting for the thickness of the liquid crystal cell.

FIG. 30 shows the deformation amount of spacer 230 when the spacer 230 is displaced after the display substrates, having the main spacer regions 201 and the first secondary spacer regions 202 which have different contact densities, is subjected to external force. In FIG. 30, a horizontal axis represents the contact density (μm²/mm²) of the first secondary spacer region 202, and a vertical axis represents the deformation of the liquid crystal cell (μm). Six lines from top to bottom in FIG. 30 represent the contact density of the main spacer region 201 as 100 μm²/mm², 150 μm²/mm², 200 μm²/mm², 250 μm²/mm², 300 μm²/mm², and 350 μm²/mm², respectively. In general, the thickness of the first signal line DL is in a range from 0.55 μm to 0.65 μm, and the thickness of the signal line group 30 is in a range from 0.65 μm to 0.75 μm. It may be clearly seen that in a case where the contact density of the first secondary spacer region 202 is greater than 15000 μm²/mm² and the contact density of the main spacer region 201 is greater than 150 μm²/mm², the deformation amount of the spacer 230 is significantly less than the thickness of the first signal line DL. In this case, the displacement of the spacer 230 will not scratch the alignment film.

the third signal line 33 is provided with a second via hole V2 (as shown in FIG. 4) near the intersection of the third signal line 33 and the first signal line DL, and the third signal line 33 is connected to the first electrode layer 21 through the second via hole V2. The second via hole V2 is disposed near the intersection of the third signal line 33 and the first signal line DL. In a case where the light leakage occurs due to the second via hole V2, the black matrix 60 may block the light leaked from the second via hole V2, thereby reducing the adverse effect of the second via hole V2 on the display effect of the display substrate 1100.

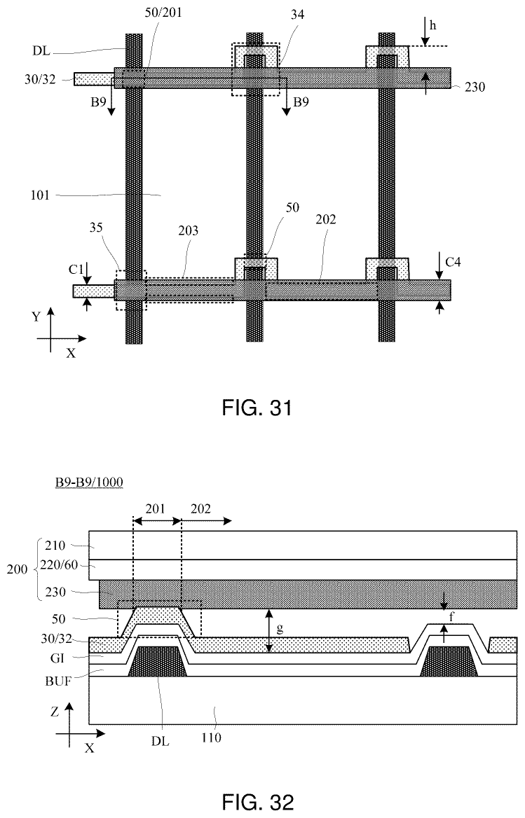

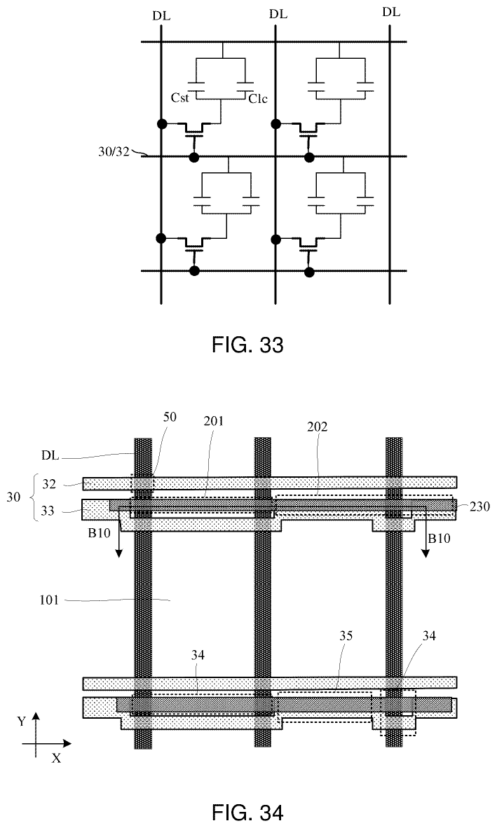

In some embodiments, referring to FIGS. 31, 32 and 33, the signal line group 30 includes a second signal line 32. The second signal line 32 controls the connection between the first signal line DL and the liquid crystal capacitor Clc and the connection between the first signal line DL and the storage capacitor Cst (the second electrode 22). That is, the second signal line 32 may control whether the first signal line DL charges the liquid crystal capacitor Clc and the storage capacitor Cst.

For example, a signal line group 30 includes a second signal line 32. The second signal line 32 may control the connection between the first signal line DL of a row of pixel regions 101 and the second electrode 22 of the row of pixel regions, and a second signal line 32 of an adjacent row of pixel regions 101 may provide a stable voltage for terminals of the liquid crystal capacitor Clc and the storage capacitor Cst.

The orthogonal projection of the spacer 230 on the array substrate 100 covers the second signal line 32 in the signal line group 30. That is, within a length range of the spacer 230, the orthogonal projection of the spacer 230 on the array substrate 100 covers the second signal line 32.

For example, a width of the spacer 230 may be C4, a width of the second signal line 32 may be C1, and an alignment deviation between the array substrate 100 and the color filter substrate 200 may be e. That is, during a process of assembling the array substrate 100 and the color filter substrate 200, the maximum alignment deviation between the array substrate 100 and the color filter substrate 200 in the second direction Y may be e, and C4 may be greater than C1. In some embodiments, C4 is greater than or equal to a sum of C1 and twice e (i.e., C4≥C1+2e). That is, the orthogonal projection of the spacer 230 on the array substrate 100 covers the second signal line 32 of the signal line group 30, and distances between two sides of the second signal line 32 and two sides of the orthogonal projection of the spacer 230 on the array substrate 100 are greater than or equal to e. In this way, in a case where a slight deviation occurs during the process of assembling the array substrate 100 and the color filter substrate 200, a width of a portion where the orthogonal projection of the spacer 230 on the array substrate 100 overlaps with the second signal line 32 is always C1. In this way, it may be ensured that the spacer 230 may provide stable support for the liquid crystal layer 300, thereby ensuring that the liquid crystal layer 300 may maintain a stable thickness, thereby ensuring the display effect of the display substrate.

In some embodiments, distances between the side of the spacer 230 away from the color filter substrate 200 and the color filter substrate 200 are equal. The overlapping regions of the first signal lines DL and the signal line groups 30 forms the plurality of columnar structures 50 protruding toward the color filter substrate 200, and the side of the spacer 230 away from the color filter substrate 200 abuts against the part of the columnar structures 50. In this way, the spacer 230 is cooperated with the first signal line DL and the signal line group 30 to form different spacer regions thereof. The portion of the side of the spacer 230 away from the color filter substrate 200 that is abuts against the part of the columnar structures 50 forms the main spacer region 201. The portion of the orthogonal projection of the spacer 230 on the array substrate 100 that overlaps with the first signal lines DL or the signal line groups 30 but not overlaps with the columnar structure 50 forms the first secondary spacer region 202.

The portion where the orthogonal projection of the spacer 230 on the array substrate 100 overlaps with the region of the array substrate 100 other than the second signal line 32 forms the second secondary spacer region 203. The side of the columnar structure 50 proximate to the color filter substrate 200 abuts against the spacer 230. The distance between the side of the region of the first signal line DL or the signal line group 30 other than the columnar structure 50 proximate to the color filter substrate 200 and the spacer 230 is f. A distance between the portion of the region of the array substrate 100 other than the second signal line 32 and the spacer 230 is g. g is greater than f, and f is greater than 0 (i.e., g>f>0). In this way, the spacer 230 is cooperated with the first signal line DL and the signal line group 30 to form the main spacer region 201, the first secondary spacer region 202 and the second secondary spacer region 203 with step differences.

In a normal state, the main spacer region 201 of the spacer 230 provides support for the thickness of the liquid crystal cell. In a case where the display substrate is pressed, the color filter substrate 200 is recessed toward a side proximate to the array substrate 100, and the first secondary spacer region 202 participates in supporting the thickness of the liquid crystal cell. In a case where the display substrate is pressed strongly, a degree of depression of the color filter substrate 200 toward the array substrate 100 is increased. In this case, the second secondary spacer region 203 also participates in supporting the thickness of the liquid crystal cell.

The signal line group 30 is provided with a plurality of wiring regions 34 along the length direction thereof. A position where at least one signal line group 30 intersects the first signal line DL is provided with the wiring region 34. In the wiring region 34, the orthogonal projection of the spacer 230 on the array substrate 100 has no overlapping region with the columnar structure 50. For example, the signal line group 30 includes a second signal line 32, and second signal line 32 extends in the non-wiring region 35 along the length direction of the signal line group 30 (i.e., the first direction X). In the wiring region 34, the second signal line 32 is bent for a distance in a direction perpendicular to the length direction of the signal line group 30, and then extends along the length direction of the signal line group 30. After bypassing the columnar structure 50, the second signal line 32 bends back and extends to a position that is colinear with the second signal line 32 in the non-wiring region 35, and then continues to extend along the length direction of the signal line group 30. That is, in the wiring region 34, the second signal line 32 protrudes along the second direction Y to avoid the spacer 230. In this way, an original main spacer region 201 in the wiring region 34 is changed into the first secondary spacer region 202.

In some embodiments, in the wiring region 34, the distance that the second signal line 32 is bent in the direction perpendicular to the length direction of the signal line group 30 (e.g., the second direction Y) is h, the maximum alignment deviation between the array substrate 100 and the color filter substrate 200 in the second direction Y is e, and h is greater than or equal to e.

In some embodiments, on average, a spacer 230 is provided for every twelve pixel regions 101 in the display substrate. For example, in twelve pixel regions 101 arranged in a row and twelve columns, a spacer 230 at least crosses over thirteen first signal lines DL in the length direction thereof, that is, the spacer 230 crosses over twelve pixel regions 101 in the length direction thereof. The orthogonal projection of the spacer 230 on the array substrate 100 has overlapping regions with the thirteen first signal lines DL and has an overlapping region with a signal line group 30. At least eleven of the intersection positions between the thirteen first signal lines DL and the signal line group 30 are provided with wiring regions 34. In this way, the contact density ratio between the main spacer region 201 and the first secondary spacer region 202 is close to 1:100. The main spacer region 201 and the first secondary spacer region 202 with this contact density ratio may satisfy the requirements of supporting the thickness of the liquid crystal cell and having no dark spots under external pressure.

In some embodiments, the spacer 230 may be disposed according to requirements. For example, a main spacer region 201 and six to twelve first secondary spacer regions 202 may be disposed in twelve pixel regions 101 arranged in two rows and six columns. Alternatively, a main spacer region 201 and six to twelve first secondary spacer regions 202 may be disposed in twenty-four pixel regions 101 arranged in three rows and four columns. It only needs to satisfy that the spacers 230 are evenly arranged on the entire surface and the contact density ratio between the main spacer region 201 and the first secondary spacer region 202 is close to 1:100. Of course, the above-mentioned arrangement of the spacer 230 and the wiring region 34 may be determined according to actual needs. For example, on average, a spacer 230 is provided for every 12, 13, 14, 15 or 16 pixel regions 101. A spacer 230 crosses over 12, 13, 14, 15 or 16 first signal lines DL in the length direction thereof, that is, the spacer 230 crosses over 11, 12, 13, 14 or 15 pixel regions 101 in the length direction thereof. The number of wiring regions 34 may also be 11, 12, 13, 14, or 15. It only needs to satisfy that the contact density of the main spacer region 201 is close to 200 μm²/mm² and the contact density of the first secondary spacer region 202 is close to 20000 μm²/mm².

The spacer 230 cross over a plurality of first signal lines DL in the length direction (e.g., first direction X) thereof. In a case where the spacer 230 is displaced greatly in the second direction Y, for example, in a case where the spacer 230 is displaced in the second direction Y to not overlap with the signal line group 30, the surface of the region where the first signal line DL is located still supports the spacer 230. That is, in a case where the spacer 230 is displaced greatly in the second direction Y, the first secondary spacer region 202 formed by the overlap of the main spacer region 201 and the signal line group 30 will be lost, but the first secondary spacer region 202 formed by the overlap of the main spacer region 201 and the first signal line DL will not be lost. Therefore, in a case where the spacer 230 is displaced greatly in the second direction Y, the spacer 230 will not scratch the alignment film on the array substrate 100.

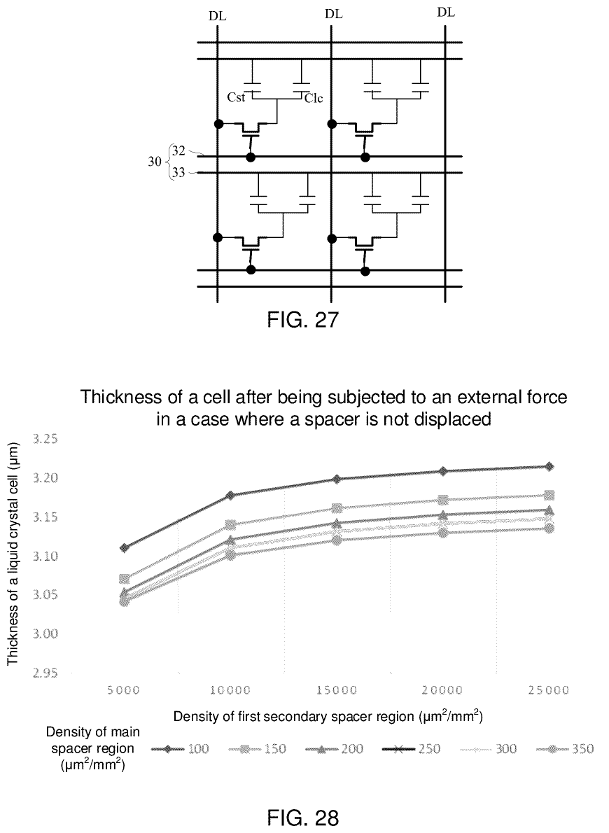

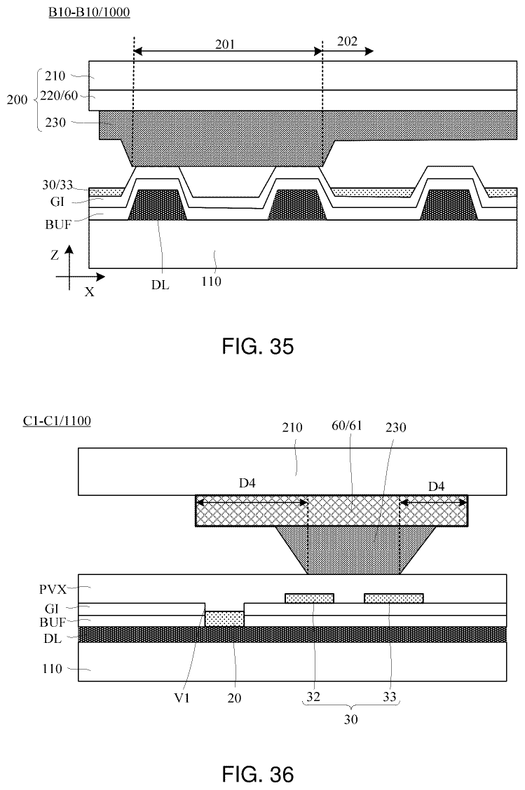

As shown in FIGS. 27 and 34 to 35, in some embodiments, the orthogonal projection of the spacer 230 on the array substrate 100 partially overlaps with the signal line group 30. Distances between the side of the spacer 230 away from the color filter substrate 200 and the color filter substrate 200 are not equal. The spacer 230 includes a main spacer region 201 having a first thickness and a first secondary spacer region 202 having a second thickness, and the first thickness is greater than the second thickness. An orthogonal projection of the main spacer region 201 on the array substrate 100 has an overlapping region with the first signal line DL, and the orthogonal projection of the main spacer region 201 on the array substrate has no overlapping region with the signal line group 30. The orthogonal projection of the main spacer region 201 on the array substrate 100 covers at least two first signal lines DL in the length direction of the spacer 230. A portion of an orthogonal projection of the first secondary spacer region 202 on the array substrate 100 overlaps with the first signal line DL, and a portion of the orthogonal projection of the first secondary spacer region 202 on the array substrate 100 overlaps with the signal line group 30.

The signal line group 30 is provided with a plurality of wiring regions 34 along the length direction thereof. A position where at least one signal line group 30 intersects the first signal line DL is provided with the wiring region 34. In the wiring region 34, the signal line group 30 may avoid the region where the spacer 230 overlaps with the first signal line DL. That is, the spacer 230, the signal line group 30 and the first signal line DL do not overlap at a same time. In addition, the wiring region 34 is further disposed at a position of the orthogonal projection of the main spacer region 201 on the array substrate 100, and the signal line group 30 in the wiring region 34 avoids the range covered by the orthogonal projection of the main spacer region 201 on the array substrate 100. The maximum alignment deviation between the array substrate 100 and the color filter substrate 200 in the second direction Y is e. A distance between the signal line group 30 in the wiring region 34 and a region where the spacer 230 overlaps with the first signal line DL is greater than e, and a distance between the signal line group 30 in the wiring region 34 and a region covered by the orthogonal projection of the main spacer region 201 on the array substrate 100 is greater than e. That is, and orthogonal projection of the first secondary spacer region 202 in the wiring region 34 on the array substrate 100 overlaps with the first signal line DL, and an orthogonal projection of the first secondary spacer region 202 in the non-wiring region 35 on the array substrate 100 overlaps with the signal line group 30.

In some embodiments, on average, a spacer 230 is provided for every twenty-four pixel regions 101 in the display substrate. For example, in twenty-four pixel regions 101 arranged in two rows and twelve columns, a spacer 230 at least crosses over thirteen first signal lines DL in the length direction thereof, that is, the spacer 230 crosses over twelve pixel regions 101 in the length direction thereof. The orthogonal projection of the spacer 230 on the array substrate 100 has an overlapping region with the thirteen first signal lines DL and has an overlapping region with a signal line group 30. Each of the intersection positions between the thirteen first signal lines DL and the signal line group 30 is provided with a wiring region 34. A spacer 230 is provided with a main spacer region 201. In this way, the contact density ratio between the main spacer region 201 and the first secondary spacer region 202 is close to 1:100. The main spacer region 201 and the first secondary spacer region 202 with this contact density ratio may satisfy the requirements of supporting the thickness of the liquid crystal cell and having no dark spots under external pressure.

For example, the spacers 230 may be disposed according to requirements. For example, a main spacer region 201 and six to twelve first secondary spacer regions 202 may be disposed in twenty-four pixel regions 101 arranged in three rows and eight columns. Alternatively, a main spacer region 201 and six to twelve first secondary spacer regions 202 may be disposed in twenty-four pixel regions 101 arranged in four rows and six columns, or the like. It only needs to satisfy that the spacers 230 are evenly arranged on the entire surface and the contact density ratio between the main spacer region 201 and the first secondary spacer region 202 is close to 1:100. Of course, the above-mentioned arrangement of the spacer 230 and the wiring region 34 may be determined according to actual needs. On average, a spacer 230 may be provided for every 23, 24, 25, 26 or 27 pixel regions 101. A spacer 230 crosses over 12, 13, 14, 15 or 16 first signal lines DL in the length direction thereof, that is, the spacer 230 crosses over 11, 12, 13, 14 or 15 pixel regions 101 in the length direction thereof. The number of wiring regions 34 may also be 11, 12, 13, 14, or 15. It only needs to satisfy that the contact density of the main spacer region 201 is close to 200 μm²/mm² and the contact density of the first secondary spacer region 202 is close to 20000 μm²/mm². The spacer 230 crosses over a plurality of first signal lines DL in the length direction thereof. In a case where the spacer 230 is displaced greatly in the second direction Y, for example, in a case where the spacer 230 is displaced in the second direction Y to not overlap with the signal line group 30, the first signal line DL may still support the spacer 230. That is, in a case where the spacer 230 is displaced greatly in the second direction Y, the first secondary spacer region 202 formed by the overlap of the main spacer region 201 and the signal line group 30 will be lost, but the first secondary spacer region 202 formed by the overlap of the main spacer region 201 and the first signal line DL will not be lost. In addition, since the main spacer region 201 of the spacer 230 overlaps with the first signal line DL, the supporting capacity of the main spacer region 201 will not be lost due to the displacement of the spacer 230 in the second direction Y. Therefore, in a case where the spacer 230 is displaced greatly in the second direction Y, the spacer 230 will not scratch the alignment film on the array substrate 100.

In some embodiments, referring to FIGS. 26 and 36, the orthogonal projection of the black matrix 60 on the array substrate 100 covers the spacer 230, the first signal line DL, and the signal line group 30.

As shown in FIG. 36, the black matrix 60 further includes a first portion 61. An orthogonal projection of the first portion 61 on the array substrate 100 covers the semiconductor pattern 10, the first pattern LS, the region where the signal line group 30 overlaps with the first signal line DL, and the region where the signal line group 30 is disposed opposite to the semiconductor pattern 10 and the first pattern LS in the second direction Y. In orthogonal projections of the first portion 61 and the surface 231 of the spacer 230 proximate to the array substrate 100 on the array substrate 100, there is a fourth interval D4 between boundaries of the orthogonal projections that are proximate to each other, and the fourth interval D4 is in a range from 20 μm to 40 μm. In this way, the first portion 61 may block the semiconductor pattern 10, the first pattern LS, a region where the signal line group 30 overlaps with the first signal line DL, and a region where the signal line group 30 is disposed opposite to the semiconductor pattern 10 and the first pattern LS in the second direction Y, so as to reduce the risk of light leakage around the above-mentioned region.

For example, the fourth interval D4 may be in a range from 20 μm to 30 μm, or the fourth interval D4 may be in a range from 30 μm to 40 μm. For example, the value of the fourth interval D4 may be 20 μm, 25 μm, 30 μm, 35 μm, or 40 μm, etc., which will not be listed one by one in the embodiments of the present disclosure.

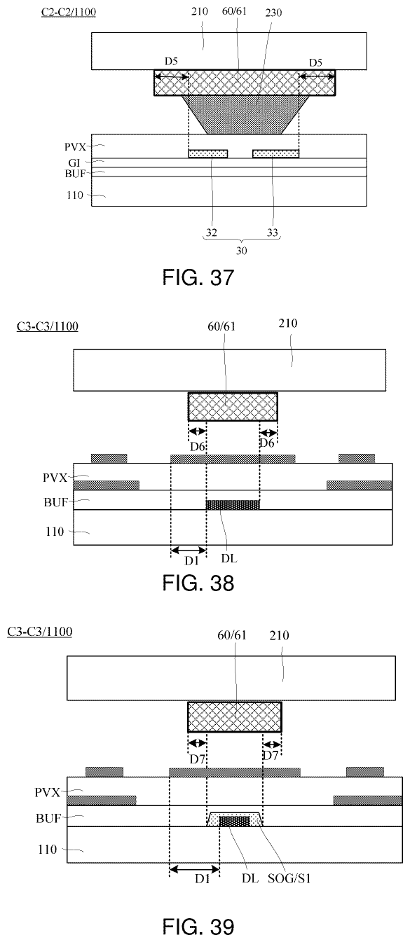

In some embodiments, referring to FIGS. 26 and 37, the black matrix 60 also includes a second portion 62, and an orthogonal projection of the second portion 62 on the array substrate 100 covers a region of the signal line group 30 that is staggered with the first pattern LS and the semiconductor pattern 10 in the second direction Y, and the portions of the black matrix 60 covering the same signal line group 30 includes a first portion 61 and a second portion 62 that are staggered along the first direction X. In orthogonal projections of the second portion 62 and the signal line group 30 on the array substrate 100, there is a fifth interval D5 between boundaries of the orthogonal projections that are proximate to each other, and the fifth interval D5 is in a range from 3 μm to 6 μm. In this way, the second portion 62 may shield the region of the signal line group 30 that is staggered with the first pattern LS and the semiconductor pattern 10 in the second direction Y, and reduce the risk of light leakage on both sides of the above-mentioned region along the second direction Y. For example, the value of the fifth interval D5 may be 3 μm, 3.5 μm, 4 μm, 5 μm, or 6 μm, etc., which will not be listed one by one in the embodiments of the present disclosure.

In some embodiments, referring to FIGS. 26 and 38, in a case where the first insulating layer BUF is directly disposed on the first conductive layer SD, the first insulating layer BUF includes a first groove portion 41 that is concave in a direction proximate to the first substrate 110, and at least a portion of the first groove portion 41 is located between the first signal line DL and the first pattern LS, the black matrix 60 further includes a third portion 63. An orthogonal projection of the third portion 63 on the array substrate 100 covers the first signal line DL. In addition, in the orthogonal projections of the third portion 63 and the first signal line DL on the first substrate 110, there is a sixth interval D6 between boundaries of the orthogonal projections that are proximate to each other, and the sixth interval D6 is in a range from 0.5 μm to 2 μm. The third portion 63 may block the reflection of ambient light by the first signal line DL, and may further reduce the risk of light leakage at both sides of the first signal line DL due to the step difference of the first signal line DL. For example, the value of the sixth interval D6 may be 0.5 μm, 1 μm, 1.5 μm, or 2 μm, etc., which will not be listed one by one in the embodiments of the present disclosure.

In some embodiments, referring to FIGS. 26 and 39, in a case where the array substrate 100 further includes a planarization layer SOG, and the planarization layer SOG is located between the first conductive layer SD and the first insulating layer BUF, the surface of the planarization layer SOG away from the first substrate 110 is a flat surface, and the planarization layer SOG includes a first flat portion S1. The first flat portion S1 covers the first signal line DL. The black matrix 60 includes a third portion 63, an orthogonal projection of the third portion 63 on the array substrate 100 covers the first flat portion S1, and in the orthogonal projections of the third portion 63 and the first flat portion S1 on the first substrate 110, there is a seventh interval D7 between boundaries of the orthogonal projections that are proximate to each other, and the seventh interval D7 is in a range from 0.5 μm to 2 μm. The third portion 63 may block the reflection of ambient light by the first signal line DL, and may further reduce the risk of light leakage at both sides of the first signal line DL caused by the step difference formed by the planarization layer SOG. For example, a value of the seventh interval D7 may be 0.5 μm, 1 μm, 1.5 μm, or 2 μm, etc., which will not be listed one by one in the embodiments of the present disclosure.

In some embodiments, in a case where the first insulating layer BUF of the array substrate 100 is directly disposed on the first conductive layer SD, and the display substrate includes the array substrate and the color filter substrate described in any of the above embodiments, the transmittance of the display substrate is greater than or equal to 6%. For example, the transmittance of the display substrate is 6%, 6.5%, 6.6%, 7%, 8% or 8.5%, etc., which will not be listed one by one in the embodiments of the present disclosure.

For example, in a case where the display substrate is lit up (the display substrate shows a maximum gray scale), the brightness of more than 9 points on the display substrate is tested by using a CCD device. Then, the brightness detected at each point is divided by the backlight brightness at a corresponding position, and an average value is taken to obtain the transmittance of the display substrate. It was found through actual testing that the transmittance of the display substrate of the embodiments of the present disclosure may reach at least 6%, which is more than 50% higher than that of a conventional ADS display substrate. In some embodiments, in a case where the array substrate 100 further includes a planarization layer SOG, the planarization layer SOG is located between the first conductive layer SD and the first insulating layer BUF, and the display substrate includes the array substrate and the color filter substrate described in any of the above embodiments, the transmittance of the display substrate is greater than or equal to 9%. For example, the transmittance of the display substrate is 9%, 9.5%, 10%, 10.5% or 11%, etc., which are not listed one by one in the embodiments of the present disclosure.

For example, in a case where the display substrate is lit up (the display substrate shows a maximum gray scale), the brightness of more than 9 points on the display substrate is tested by using a CCD device. Then, the brightness detected at each point is divided by the backlight brightness at a corresponding position, and an average value is taken to obtain the transmittance of the display substrate. It was found through actual testing that the transmittance of the display substrate of the embodiment of the present disclosure can reach at least 9%, which is more than 40% higher than that of a conventional display substrate.

The above are only specific embodiments of the present disclosure, but the scope of protection of the present disclosure is not limited thereto, and any person skilled in the art may conceive of variations or replacements within the technical scope of the present disclosure, which shall fall within the protection scope of the present disclosure. Therefore, the protection scope of the present disclosure should be determined by the protection scope of the claims.

1. A display substrate, comprising an array substrate and a color filter substrate; wherein the array substrate includes:
a first substrate;
a first conductive layer disposed on a side of the first substrate, and including at least one first signal line and a first pattern that are spaced apart;
a first insulating layer disposed on a side of the first conductive layer away from the first substrate;
a first via hole at least penetrating the first insulating layer and exposing at least a portion of the first signal line;
a semiconductor layer disposed on a side of the first insulating layer away from the first substrate, and including a semiconductor pattern; wherein the semiconductor pattern includes a first portion, a second portion and a channel structure located between the first portion and the second portion; an orthogonal projection of the first portion on the first substrate partially overlaps with an orthogonal projection of the first signal line on the first substrate, and an orthogonal projection of the channel structure on the first substrate is located within a range of an orthogonal projection of the first pattern on the first substrate; and
a connecting electrode disposed on a side of the semiconductor layer away from the first substrate; at least a portion of the connecting electrode being located in the first via hole and connected to the first portion and the first signal line.

2. The display substrate according to claim 1, wherein
the array substrate further includes a first electrode; the first electrode is disposed on a side of a film layer where the connecting electrode is located away from the first substrate, and an orthogonal projection of the first electrode on the first substrate covers the orthogonal projection of the first signal line on the first substrate; or
the array substrate further includes the first electrode; the first electrode is disposed on the side of the film layer where the connecting electrode is located away from the first substrate, and the orthogonal project of first electrode on the first substrate covers the orthogonal projection of the first signal line on the first substrate; and
the first electrode includes a first extending segment: an extending direction of the first extending segment is the same as an extending direction of the first signal line; an orthogonal projection of the first extending segment on the first substrate covers the orthogonal projection of the first signal line on the first substrate, and there is a first interval between boundaries, proximate to each other, of the orthogonal projections of the first extending segment and the first signal line on the first substrate; the first interval is in a range from 2 μm to 5 μm.

3. (canceled)

4. The display substrate according to claim 1, wherein
the semiconductor layer further includes a second electrode connected to the second portion and integrally disposed with the second portion.

5. The display substrate according to claim 4, wherein there is a second interval between an orthogonal projection of the second electrode on the first substrate and an orthogonal projection of the first pattern on the first substrate, and there is a third interval between the orthogonal projection of the second electrode on the first substrate and the orthogonal projection of the first signal line on the first substrate.

6. The display substrate according to claim 5, wherein
the first insulating layer includes a first groove portion that is concave in a direction proximate to the first substrate, and at least a portion of the first groove portion is located between the first signal line and the first pattern; and
the second interval is greater than or equal to 2 μm, and/or the third interval is greater than or equal to 5 μm; or
the array substrate further includes a planarization layer; the planarization layer is located between the first conductive layer and the first insulating layer; a surface of the planarization layer away from the first substrate is a flat surface; and
orthogonal projections of the first conductive layer, the second interval and the third interval on the first substrate are located within a range of an orthogonal projection of the planarization layer on the first substrate; the second interval is greater than or equal to 1 μm, and/or the third interval is greater than or equal to 3 μm.

7. (canceled)

8. The display substrate according to claim 1, wherein
the first insulating layer includes a first groove portion that is concave in a direction proximate to the first substrate, and at least a portion of the first groove portion is located between the first signal line and the first pattern; the first groove portion includes two first side walls disposed opposite to each other;
the first portion includes two first sub-portions covering the two first side walls, and a second sub-portion covering other regions of the first insulating layer; a thickness of the first sub-portion is less than a thickness of the second sub-portion.

9. The display substrate according to claim 8, wherein
the array substrate further includes a second insulating layer; the second insulating layer is disposed between the semiconductor layer and a film layer where the connecting electrode is located; and
one of the two first sub-portions proximate to the first signal line is a target sub-portion; the first via hole penetrates the second insulating layer and exposes the target sub-portion; the connecting electrode covers the target sub-portion; a dimension of the channel structure in a direction perpendicular to the first substrate is greater than or equal to 300 Å: or
the array substrate further includes the second insulating layer, the second insulating layer is disposed between the semiconductor layer and the film layer where the connecting electrode is located, and
one of the two first sub-segments proximate to the first signal line is the target sub-segment; the first via hole further penetrates the second insulating layer, and there is an interval between the first via hole and the target sub-segment; the dimension of the channel structure in the direction perpendicular to the first substrate is greater than or equal to 100 Å; or
the array substrate further includes the second insulating layer; the second insulating layer is disposed between the semiconductor layer and the film layer where the connecting electrode is located; and
one of the first sub-segments proximate to the first signal line is the target sub-segment; the first via hole penetrates the second insulating layer and exposes the target sub-segment; there is an interval between the connecting electrode and the target sub-segment; the dimension of the channel structure in the direction perpendicular to the first substrate is greater than or equal to 600 Å; or
along the direction perpendicular to the first substrate, a dimension of the first conductive layer is in a range from 0.4 μm to 0.8 μm; and/or
in a cross section perpendicular to the first substrate and perpendicular to an extending direction of an edge of the first conductive layer, the side wall of the first conductive layer and the first substrate have a first included angle therebetween, and the first included angle is less than or equal to 50°.

10-12. (canceled)

13. The display substrate according to claim 1, wherein
the array substrate further includes a planarization layer; the planarization layer is located between the first conductive layer and the first insulating layer, and a surface of the planarization layer away from the first substrate is a flat surface; the planarization layer at least covers the first signal line, the first pattern, and an interval between the first signal line and the first pattern;
wherein the semiconductor layer further includes a second electrode; the second electrode is connected to the second portion and integrally disposed with the second portion; at least a portion of an orthogonal projection of the second electrode on the first substrate does not overlap with at least a portion of an orthogonal projection of the planarization layer on the first substrate.

14. The display substrate according to claim 13, wherein, in a cross section perpendicular to the first substrate and perpendicular to an extending direction of a side wall of the planarization layer, the side wall of the planarization layer and the first substrate have a second included angle therebetween, and the second included angle is less than or equal to 50°; and/or an interval between the surface of the planarization layer away from the first substrate and the first substrate is in a range from 0.4 μm to 0.8 μm.

15. The display substrate according to claim 1, wherein
the at least one first signal line includes a plurality of first signal lines; the plurality of first signal lines are disposed at intervals along a first direction and extend along a second direction;
the array substrate further includes a plurality of signal line groups; the plurality of signal line groups are arranged at intervals along the second direction and extend along the first direction;
the plurality of first signal lines and the plurality of signal line groups intersect each other to form a grid structure; a region where an orthogonal projection of any one of the plurality of signal line groups on the first substrate overlaps with an orthogonal projection of any one of the plurality of first signal lines on the first substrate protrudes toward a side away from the first substrate to form a columnar structure;
the color filter substrate includes at least one spacer, the spacer is in a strip shape and extends along the first direction; an orthogonal projection of the spacer on the array substrate partially overlaps with the first signal line and the signal line group;
the signal line group includes a wiring region; a position where at least one of the signal line groups intersects with the first signal line is provided with the wiring region; in the wiring region, the orthogonal projection of the spacer on the array substrate does not overlap with the columnar structure.

16. The display substrate according to claim 15, wherein
a side of the spacer away from the color filter substrate abuts against a portion of the columnar structure; or
the side of the spaces away from the color filter substrate abuts against the portion of the columnar structure; and
the side of the spacer away from the color filter substrate is at a same distance from the color filter substrate: or
in the wiring region, the signal line group protrudes toward the first direction; of
a dimension of the spacer along the first direction is greater than a distance between two adjacent first signal lines; or
the signal line group and the connecting electrode are made of a same material are disposed on a same layer.

17-20. (canceled)

21. The display substrate according to claim 16, wherein the signal line group includes one or more second signal line; an orthogonal projection of the one or more second signal line on the color filter substrate overlaps with the spacer; a dimension of any one of the one or more second signal line in the second direction is C1; a dimension of an end of the spacer proximate to the array substrate in the second direction is C4; C4 is greater than C1.

22. The display substrate according to claim 16, wherein
the signal line group includes one or more second signal line and one or more third signal line; the orthogonal projection of the spacer on the array substrate covers a region between the second signal line and the third signal line; the orthogonal projection of the spacer on the array substrate partially overlaps with the second signal line; the orthogonal projection of the spacer on the array substrate partially overlaps with the third signal line.

23. The display substrate according to claim 22, wherein
a dimension of the second signal line in the second direction is C1, and a dimension of the third signal line in the second direction is C2; an interval between the second signal line and the third signal line is C3, and a dimension of an end of the spacer proximate to the array substrate in the second direction is C4;
C1, C2, C3 and C4 satisfy: C2>C1, C4=C3+C1; or
C1, C2, C3 and C4 satisfy: C1>C2 ,C4=C3+C2; or
a position where at least one of the one or more second signal lines and/or at least one of the one or more third signal lines intersects the first signal line is provided with the wiring region; or
the position where at least one of the one or more second signal lines and/or at least one of the one or more third signal lives intersects the first signal line is provided with the wiring the array substrate includes a first electrode, and the third signal line is connected to the first electrode at a side of the protrusion in the wiring region along the first direction.

24. (canceled)

25. (canceled)

26. The display substrate according to claim 16, wherein
an orthogonal projection of one of the at least one spacer on the array substrate has overlapping regions with at least thirteen of the at least one first signal line, and has an overlapping region with one of the plurality of signal line groups; at least eleven of intersection positions between the at least thirteen first signal lines and the signal line group are provided with the wiring region.

27. The display substrate according to claim 26, wherein
the grid structure formed by the plurality of the first signal lines and the plurality of the signal line groups defines a plurality of pixel regions; on average, every twenty-four pixel regions in the display substrate is provided with one of the at least one spacer.

28. The display substrate according to claim 16, wherein
the orthogonal projection of the spacer on the array substrate partially overlaps with the signal line group or the first signal line; the spacer includes a main spacer region with a first thickness and a secondary spacer region with a second thickness, and the first thickness is greater than the second thickness; an orthogonal projection of the main spacer region on the array substrate has an overlapping region with the first signal line, and an orthogonal projection of the main spacer region on the array substrate does not overlap with the signal line group; and/or,
the orthogonal projection of the main spacer region on the array substrate has two least one first signal line.

29. (canceled)

30. The display substrate according to claim 16, wherein
the color filter substrate further includes a black matrix; an orthogonal projection of the black matrix on the array substrate covers the spacer, the first signal line and the signal line group.

31. The display substrate according to claim 30, wherein
the black matrix includes a first portion, and an orthogonal projection of the first portion on the array substrate covers the semiconductor pattern, the first pattern, and the region where the signal line group overlaps with the first signal line; there is a fourth interval D4 between boundaries, of orthogonal projections of the first portion and a surface of the spacer proximate to the array substrate on the array substrate, that are proximate to each other; the fourth interval is in a range from 20 μm to 40 μm; or
the black matrix further includes a second portion; an orthogonal projection of the second portion on the array substrate covers a region of the signal line group that is staggered with the first pattern and the semiconductor pattern in the second direction, and a portion of the black matrix covering a same signal line group includes first portions and the second portions that are staggered along the first direction; there is a fifth interval between boundaries, of orthogonal to each other: the fifth interval is in a range from 3 μm to 6 μm; or
the first insulating layer includes a first groove portion that is concave in a direction proximate to the first substrate, and at least a portion of the first groove portion is located between the first signal live and the first pattern; and
the black matrix further includes a third portion; an orthogonal projection of the third portion on the array substrate covers the first signal line, and there is a sixth interval between boundaries, of orthogonal projections of the third portion and the first signal line on the first substrate, that are proximate to each other, the sixth interval is in a range from 0.5 μm to 2 μm; or
the black matrix further includes the third portion; the orthogonal protection of the third portion on the array substrate covers the first signal line, and there is the sixth interval between boundaries, of the orthogonal projections of the third portion and the first signal line on the first substrate, that are proximate to each other; the sixth interval is in the range from 0.5 μm to 2 μm; and
a transmittance of the display substrate is greater than or equal to 6%; or
the array substrate further includes a planarization layer; the planarization layer is located between the first conductive layer and the first insulated layer, and a surface of the planarization layer away from the first substrate is a flat surface; the planarization layer includes a first flat portion, and the first flat portion covers the first signal line; and
the black matrix includes the third portion; an orthogonal projection of the third portion on the array substrate covers the first flat portion, and there is a seventh interval between boundaries, of orthogonal projections of the third portion and the first flat portion on the first substrate, that proximate to each other, the seventh interval is in a range from 0.5 μm to 2 μm; or
the array substrate further includes the planarization layer; the planarization layer is located between the first conductive layer and the first insulating layer, and the surface of the planarization layer away from the first substrate is the flat surface; the planarization layer includes the first flat portion, and the first flat portion covers the first signal line;
the black matrix includes the third portion; the orthogonal projection of the third portion on the array substrate covers the first flat portion, and there is the seventh interval between boundaries, of orthogonal projections of the third portion and the first flat portion on the first substrate, that are proximate to each other; the seventh interval is in the range from 0.5 μm to 2 μm; and
transmittance of the display substrate is greater than or equal to 9%.

32-36. (canceled)

37. A display device, comprising:
the display substrate according to claim 1; and
a driving circuit board electrically connected to the display substrate, and configured to transmit a control signal to the display substrate.
